(19) United States
(12) Patent Application Publication
(10) Pub. No.: US 2025/0174967 A1
(43) Pub. Date: May 29, 2025

(54) LIGHT SOURCE DEVICE AND RANGING DEVICE

(71) Applicant: CANON KABUSHIKI KAISHA, Tokyo (JP)

(72) Inventors: TAKAKO SUGA, Kanagawa (JP); TAKESHI UCHIDA, Kanagawa (JP); TATSURO UCHIDA, Tokyo (JP)

(21) Appl. No.: 18/948,074

(22) Filed: Nov. 14, 2024

(30) Foreign Application Priority Data
Nov. 28, 2023 (JP) 2023-200586

(51) Int. Cl. H01S 5/42; G01S 7/481; H01S 5/02345; H01S 5/042; H01S 5/183

(52) U.S. Cl. CPC H01S 5/426; G01S 7/4814; H01S 5/02345; H01S 5/042; H01S 5/18361; H01S 5/18397

(57) ABSTRACT

Alight source device includes a plurality of semiconductor light emitting elements configured to stack, on a first surface side of a semiconductor substrate, a first reflector, a first semiconductor resonator including a first active layer, a second reflector, and a first electrode in order, and to stack a second electrode on a second surface of the semiconductor substrate opposite to the first surface. A power supply pad supplies power to the plurality of semiconductor light emitting elements. The plurality of semiconductor light emitting elements are divided into a plurality of groups according to a distance from the power supply pad. The semiconductor light emitting element in the group with a shorter distance to the power supply pad is configured to have a larger resistance value between the first electrode and the second electrode.

### BACKGROUND

### Field

The present disclosure relates to a light source device and a ranging device.

### Description of the Related Art

Conventionally, as the ranging device for measuring a distance to an object, a LiDAR (Light Detection and Ranging) system of a ToF (Time of Flight) method is known. As a light source for the LiDAR system, a VCSEL (Vertical Cavity Surface Emitting LASER) is desirably used because of its advantages such as low wavelength dependency with respect to temperature.

Since the light source of the LiDAR system has a longer ranging distance as power is larger, a plurality of semiconductor light emitting elements may be arranged in an array so as to be capable of coping with flash driving in which an entire surface emits light at the same time. In addition, the light source of the LiDAR system may be configured to support sequential driving in which one column or several columns are sequentially emitted. Japanese Patent Application Laid-Open No. 2021-136307 describes an example in which the number of semiconductor light emitting elements can be 100 to 1000, and an output is increased by increasing the number of semiconductor light emitting elements.

Here, since power consumption of the light source of the LiDAR system increases as an output of the semiconductor light emitting element increases, it is designed to reduce element resistance in order to reduce the power consumption. Japanese Patent Application Laid-Open No. 2021-136319 discloses an example in which the element resistance is reduced by increasing a doping concentration of an upper reflector which is a current path in the semiconductor light emitting element.

### SUMMARY

However, in a case where a light source device including the plurality of semiconductor light emitting elements was configured using the above-described conventional technique, light emission in each semiconductor light emitting element was not uniform.

Therefore, an object of the present invention is to provide a light source device capable of improving uniformity of light emission in a plurality of semiconductor light emitting elements.

According to one disclosure of the present specification, there is provided a light source device including: a plurality of semiconductor light emitting elements configured to stack, on a first surface side of a semiconductor substrate, a first reflector, a first semiconductor resonator including a first active layer, a second reflector, and a first electrode in order, and to stack a second electrode on a second surface of the semiconductor substrate opposite to the first surface; a power supply pad configured to supply power to the plurality of semiconductor light emitting elements; and a wire configured to connect each of the plurality of semiconductor light emitting elements to the power supply pad; wherein the plurality of semiconductor light emitting elements are divided into a plurality of groups according to a distance from the power supply pad, and each of the plurality of groups includes at least one semiconductor light emitting element, and wherein the semiconductor light emitting element in the group with a shorter distance to the power supply pad is configured to have a larger resistance value between the first electrode and the second electrode.

Further features of the present invention will become apparent from the following description of exemplary embodiments with reference to the attached drawings.

### BRIEF DESCRIPTION OF THE DRAWINGS

FIG. 1 is a plan view illustrating a configuration example of a VCSEL array according to a first embodiment.

FIGS. 2A and 2B are cross-sectional views illustrating a configuration example of the VCSEL according to the first embodiment.

FIG. 3 is a table illustrating a material example of a semiconductor layer added to the VCSEL according to the first embodiment and an increase rate of a resistance value due to addition of the semiconductor layer.

FIG. 4 is a plan view illustrating a configuration example of the VCSEL array according to a comparative example.

FIG. 5 is a graph illustrating a current distribution in each VCSEL array according to the first and second embodiments.

FIG. 6 is a cross-sectional view illustrating a configuration example of an epitaxial wafer according to the first embodiment.

FIGS. 7A, 7B, 7C, 7D, 7E, 7F, 7G, 7H, 7I, and 7J are cross-sectional views illustrating a manufacturing process of the VCSEL array according to the first embodiment.

FIG. 8 is a cross-sectional view illustrating a configuration example of an epitaxial wafer according to a second embodiment.

FIG. 9 is a cross-sectional view illustrating a configuration example of a VCSEL according to the second embodiment.

FIG. 10 is a plan view illustrating a configuration example of a VCSEL array according to a third embodiment.

FIG. 11 is a cross-sectional view illustrating a configuration example of the VCSEL according to the third embodiment.

FIG. 12 is a graph illustrating a relationship between a width of an insulation opening and a magnification of resistance according to the third embodiment.

FIG. 13 is a graph illustrating a current distribution in each VCSEL array according to the third and fourth embodiments.

FIG. 14 is a plan view illustrating a configuration example of a VCSEL array according to the fourth embodiment.

FIG. 15 is a table illustrating a relationship between a width of an insulation opening and a resistance value according to the fourth embodiment.

FIG. 16 is a graph illustrating a relationship between a current density and a pulse generation timing according to a fifth embodiment.

FIG. 17 is a graph illustrating a relationship between the current density and a pulse delay time according to the fifth embodiment.

FIG. 18 is a plan view illustrating a configuration example of a VCSEL array according to the fifth embodiment.

FIG. 19 is a cross-sectional view illustrating a configuration example of a high peak value VCSEL according to the fifth embodiment.

FIG. 20 is a plan view illustrating a configuration example of a VCSEL array according to a sixth embodiment.

FIGS. 21A and 21B are cross-sectional views illustrating a configuration example of the VCSEL according to the sixth embodiment.

FIG. 22 is a graph illustrating a relationship between an area of a non-oxidized region and a resistance value according to the sixth embodiment.

FIG. 23 is a plan view illustrating a configuration example of a VCSEL array according to a seventh embodiment.

FIG. 24 is a table illustrating a relationship between a width of a non-oxidized region and a resistance value according to an eighth embodiment.

FIG. 25 is a graph illustrating a current distribution in each VCSEL array according to the eighth embodiment.

FIG. 26 is a plan view illustrating a configuration example of a VCSEL array according to a ninth embodiment.

FIGS. 27A and 27B are cross-sectional views illustrating a configuration example of the VCSEL according to the ninth embodiment.

FIG. 28 is a cross-sectional view illustrating a configuration example of a VCSEL array according to a tenth embodiment.

FIG. 29 is a block diagram illustrating a configuration example of a ranging device according to an eleventh embodiment.

### DESCRIPTION OF THE EMBODIMENTS

### First Embodiment

A VCSEL array (a light source device) 100 according to the first embodiment will be described. The VCSEL array 100 is a semiconductor laser that includes a plurality of VCSELs 1 arranged in an array and emits laser light from each VCSEL 1. Here, the array refers to a state in which the plurality of VCSELs 1 is two-dimensionally arranged in accordance with a predetermined pattern.

In the following description, a first direction (a row direction) when arranging the plurality of VCSELs 1 in an array is referred to as an X direction. A second direction (a column direction) when arranging the plurality of VCSELs 1 in an array is referred to as a Y direction. A direction intersecting the X direction and the Y direction is referred to as a Z direction. The X direction, the Y direction, and the Z direction are typically orthogonal to each other.

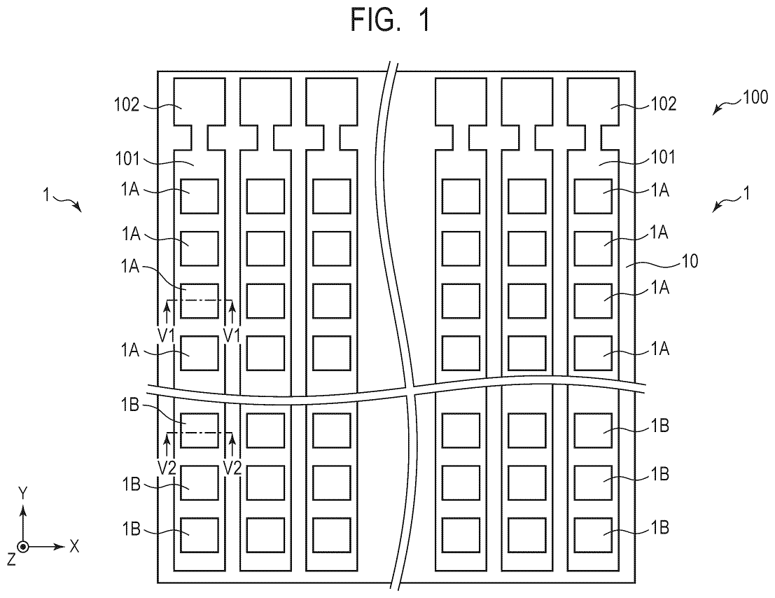

For example, as illustrated in FIG. 1, the VCSEL array 100 includes the plurality of VCSELs 1 as a plurality of semiconductor light emitting elements, a plurality of anode wires 101 as wires, and a plurality of anode power supply pads 102 as power supply pads. FIG. 1 illustrates four VCSELs 1 on one side in the Y direction and three VCSELs 1 on the other side in the Y direction among the plurality of VCSELs 1.

Each of the VCSELs 1 is a vertical cavity surface emitting laser including a distributed Bragg reflector (DBR). The plurality of VCSELs 1 is arranged in an array over a plurality of rows and a plurality of columns. For example, twenty VCSELs 1 are arrayed in one column in the Y direction, and twenty bundles of the twenty arrays in the Y direction are arrayed in the X direction. As a result, a total of four hundred (20×20) VCSELs 1 are arranged in an array, and have a rectangular shape as a whole when viewed from the Z direction.

The plurality of anode wires 101 are wires that connect each of the plurality of VCSELs 1 to the anode power supply pad 102. Each of the plurality of anode wires 101 extends in the Y direction and is provided side by side in the X direction. One anode wire 101 is electrically connected to twenty VCSELs 1 in the Y direction. In other words, the twenty VCSELs 1 in the Y direction are connected in parallel to one anode wire 101. Then, twenty such anode wires 101 are provided side by side in the X direction. As described above, the plurality of anode wires 101 are configured as sequential anode wires. Each anode wire 101 supplies current to twenty VCSELs 1 connected in parallel.

The anode power supply pad 102 is a portion for connecting an Au wire (not illustrated). The anode power supply pad 102 is a power supply pad for supplying power to the plurality of VCSELs 1, and is provided at one end of the anode wire 101 in the Y direction. The anode power supply pad 102 has a function of supplying current supplied from an outside through the Au wire to the anode wire 101.

The VCSEL array 100 configured as described above can cause the four hundred VCSELs 1 to emit light by being supplied current from the outside to the twenty anode power supply pads 102 via Au wires. By sequentially being supplied current from the outside to the twenty anode power supply pads 102, sequential driving in which each column emits light at different timings can be performed.

Here, the plurality of VCSELs 1 according to the first embodiment are configured to include a VCSEL 1A as a semiconductor light emitting element and a VCSEL 1B as a semiconductor light emitting element. In the following description, the VCSEL 1A and the VCSEL 1B may be simply referred to as “VCSEL 1” when it is not necessary to distinguish them from each other.

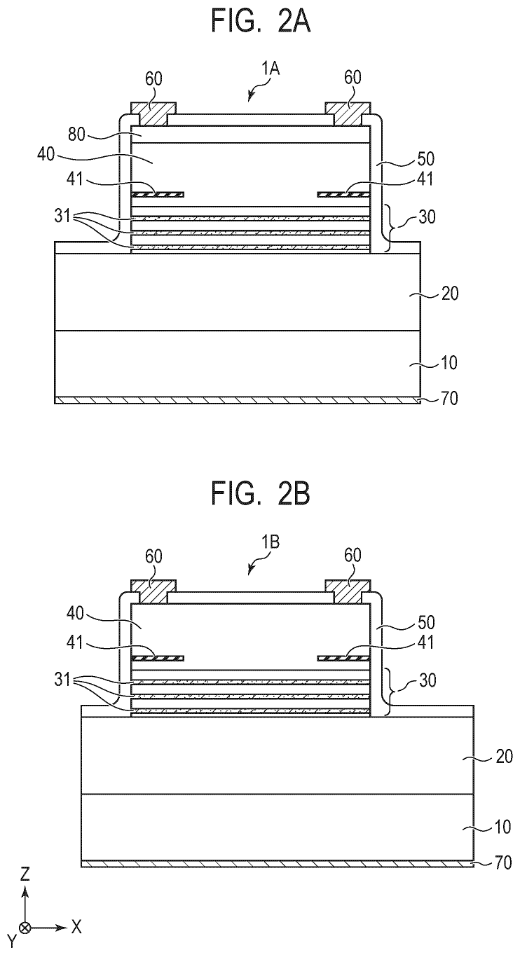

As illustrated in FIG. 2B, the VCSEL 1B includes an n-type GaAs substrate 10 as a semiconductor substrate, a first DBR 20 as a first reflector, a semiconductor resonator 30 as a first semiconductor resonator, and a second DBR 40 as a second reflector. Further, the VCSEL 1B includes an insulating film 50, an upper electrode 60 (for example, an upper ring electrode) as a first electrode, and a back electrode 70 as a second electrode. The first DBR 20, the semiconductor resonator 30, the second DBR 40, and the upper electrode 60 are stacked in this order on a first surface of the n-type GaAs substrate 10. The back electrode 70 is provided on a second surface opposite to the first surface of the n-type GaAs substrate 10. Although these members are in direct contact with each other in FIG. 2B, other members may be provided therebetween in the VCSEL 1B. In addition, the above description represents a structure, and does not limit an order of manufacturing each member. FIG. 2B is a cross-sectional view along line V2-V2 of FIG. 1.

The n-type GaAs substrate 10 is made of an n-type GaAs single crystal. The n-type GaAs substrate 10 has a first surface on which various members are stacked, and a second surface located opposite to the first surface in the Z direction.

The first DBR 20 is provided on the first surface of the n-type GaAs substrate 10. The first DBR 20 is formed by stacking 35 pairs of an Al_{0.1}GaAs layer and an Al_{0.9}GaAs layer each having an optical film thickness of ¼ λc as one pair. Here, a center wavelength λc of a high reflection band of the second DBR 40 is, for example, 940 nm.

The semiconductor resonator 30 is provided on the first DBR 20, and includes an n-type AlGaAs layer, a first active layer, and a p-type layer from the first DBR 20 side. The first active layer is a non-doped layer and has three quantum well layers 31 therein. Each of the three quantum well layers 31 includes an InGaAs well layer having a thickness of 8 nm and an AlGaAs barrier layer having a thickness of 10 nm sandwiching the InGaAs well layer.

The second DBR 40 is provided on the semiconductor resonator 30 and is formed by stacking 20 pairs of an Al_{0.1}GaAs layer and an Al_{0.9}GaAs layer each having an optical film thickness of ¼ λc as one pair. A current confinement layer 41 having a thickness of 30 nm is provided in the second DBR 40. The current confinement layer 41 is partially oxidized from a mesa lateral direction (X direction, Y direction) by being exposed to a water vapor atmosphere in the manufacturing process. The current confinement layer 41 is divided into an oxidized region having a predetermined width from the mesa sidewall and a non-oxidized region near the mesa center. Since current injected into the VCSEL 1B flows only in the non-oxidized region, only the central portion of the VCSEL 1B oscillates laser light. The upper electrode 60 is in electrical contact with the second DBR 40. A part of the Al_{0.1}GaAs layer of the uppermost layer of the second DBR 40 is replaced with a GaAs contact layer having a thickness of 50 nm and a carrier concentration of 1×10¹⁹ cm³. Thus, the second DBR 40 has improved electrical contact with the upper electrode 60. The semiconductor resonator 30 and the second DBR 40, which are layers on the upper side of the first DBR 20, are configured in such a manner that a portion in a surface of a chip is removed in the manufacturing process and the remaining portion is formed in the mesa shape.

The insulating film 50 covers the mesa-shaped semiconductor resonator 30, the second DBR 40, and the like, and suppresses alteration of these elements.

The upper electrode 60 is provided on the second DBR 40 and electrically connected to the anode wire 101. The upper electrode 60 has an annular conductive pattern, and a central opening of the upper electrode 60 serves as a circular window for light extraction. The upper electrode 60 is in ohmic contact with the second DBR 40 through a portion where a part of the insulating film 50 is removed.

The back electrode 70 has conductivity and is provided on a second surface of the n-type GaAs substrate 10. The back electrode 70 is in ohmic contact with the n-type GaAs substrate 10.

In the VCSEL 1B configured as described above, when current is applied to the upper electrode 60 via the anode wire 101, current flows through the semiconductor resonator 30 via the upper electrode 60, and thereby light is generated in the semiconductor resonator 30. Then, the light generated in the semiconductor resonator 30 resonates between the first DBR 20 and the second DBR 40 to cause laser oscillation, and the laser-oscillated light is emitted from the central opening of the upper electrode 60 in the Z direction.

Next, the VCSEL 1A will be described. The VCSEL 1A is different from the VCSEL 1B in that a semiconductor layer 80 is provided, and otherwise has the same configuration as the VCSEL 1B. That is, as illustrated in FIG. 2A, the VCSEL 1A includes the n-type GaAs substrate 10, the first DBR 20, the semiconductor resonator 30, the second DBR 40, the insulating film 50, the upper electrode 60, the back electrode 70, and the semiconductor layer 80. The first DBR 20, the semiconductor resonator 30, the second DBR 40, the semiconductor layer 80, and the upper electrode 60 are stacked in this order on the first surface of the n-type GaAs substrate 10. The back electrode 70 is provided on the second surface opposite to the first surface of the n-type GaAs substrate 10. FIG. 2A is a cross-sectional view along line V1-V1 of FIG. 1. Since the n-type GaAs substrate 10, the first DBR 20, the semiconductor resonator 30, the second DBR 40, the insulating film 50, the upper electrode 60, and the back electrode 70 have the same configuration as the VCSEL 1B described above, detailed description thereof will be omitted.

The semiconductor layer 80 is for setting a resistance value (a device resistance value) between the upper electrode 60 and the back electrode 70 of the VCSEL 1A to a value different from a resistance value between the upper electrode 60 and the back electrode 70 of the VCSEL 1B. The semiconductor layer 80 is provided between the upper electrode 60 and the second DBR 40. In other words, the semiconductor layer 80 is stacked on the opposite side of the second DBR 40 to the semiconductor resonator 30 in the Z direction. Since the VCSEL 1A includes the semiconductor layer 80, a series resistance component between the upper electrode 60 and the second DBR 40 is larger than that of the VCSEL 1B. That is, the VCSEL 1A is formed such that a distance between the upper electrode 60 and the back electrode 70 is longer than that of the VCSEL 1B. The resistance value of the VCSEL 1A between the upper electrode 60 and the back electrode 70 is larger than that of the VCSEL 1B because the distance of the VCSEL 1A is longer than that of the VCSEL 1B. The resistance value of the VCSEL 1A can be changed by changing a material, a composition, and a film thickness of the semiconductor layer 80.

As described above, the VCSEL 1A has the semiconductor layer 80 between the upper electrode 60 and the second DBR 40, while the VCSEL 1B does not have the semiconductor layer 80 between the upper electrode 60 and the second DBR 40. Thus, the VCSEL 1A and the VCSEL 1B have different resistance values between the upper electrode 60 and the back electrode 70. When a first resistance value between the upper electrode 60 and the back electrode 70 of the VCSEL 1A is R1 and a second resistance value between the upper electrode 60 and the back electrode 70 of the VCSEL 1B is R2, R1>R2. That is, the VCSEL 1A has a larger resistance value than that of the VCSEL 1B.

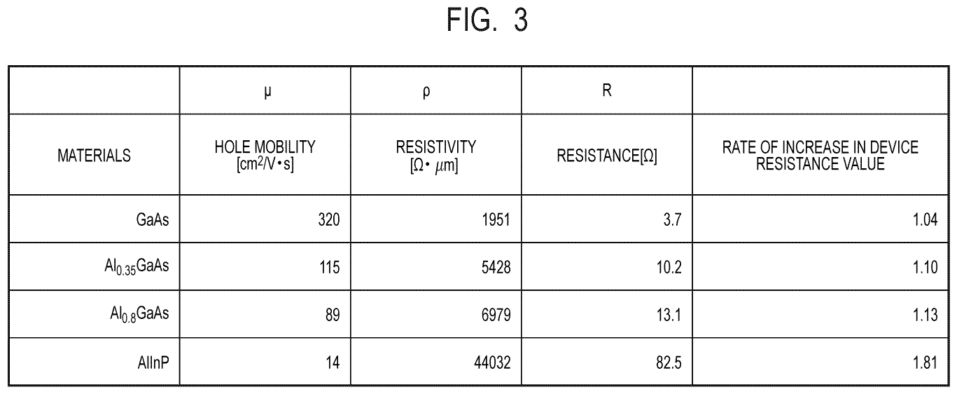

FIG. 3 is a table illustrating examples of materials of the semiconductor layer 80 and various electrical characteristics thereof. In the figure, an increase rate of the device resistance value indicates an increase rate of the resistance value for each thickness of 1 μm. A doping concentration of each material is assumed to be 1×10¹⁷ cm⁻³. By disposing the semiconductor layer 80 on the second DBR 40, the resistance of the VCSEL 1A can be increased. In the semiconductor layer 80, AlInP having a carrier concentration of 1×10¹⁷ cm⁻³ is stacked from a side close to the second DBR 40, and a GaAs contact layer having a thickness of 50 nm and a carrier concentration of 1×10¹⁹ cm⁻³ is formed thereon. Thus, the semiconductor layer 80 forms a two-layer structure. The optical film thickness of the semiconductor layer 80 is desirably selected from an integral multiple of ½ λc in order to suppress an optical influence of the addition of this layer. In the first embodiment, by setting the thickness of the AlInP layer to 403 nm, the optical film thickness of the semiconductor layer 80 can be 3/2 λc. With such a configuration, the resistance value of the VCSEL 1A can be 1.33 times that of the VCSEL 1B.

In the VCSEL array 100, the two types of VCSELs 1A and 1B having different resistance values are arranged so that the current injected into the VCSELs 1A and 1B are uniform. Here, the plurality of VCSELs 1 is divided into a plurality of groups according to a wire resistance from the anode power supply pad 102. For example, the plurality of VCSELs 1 may be divided into the plurality of groups according to a distance from the anode power supply pad 102. The plurality of groups may include, for example, a first group and a second group. The first group may include the VCSEL 1 having a shorter distance from the anode power supply pad 102 than the second group. The second group may include the VCSEL 1 having a longer distance from the anode power supply pad 102 than the first group. Here, the VCSEL 1 included in the first group and the VCSEL 1 included in the second group have different resistance values. That is, the VCSEL 1 included in the second group has a smaller resistance value than that of the VCSEL 1 included in the first group. In other words, the VCSEL 1 included in the first group has a larger resistance value than that of the VCSEL 1 included in the second group. As described above, the VCSELs are configured such that the groups with a shorter distance to the anode power supply pad 102 have higher resistance values. For example, the VCSELs are configured such that the groups with a lower wiring resistance to the anode power supply pad 102 have higher resistance values. Specifically, the VCSEL 1A configures the VCSEL of the first group having a short distance from the anode power supply pad 102, and the VCSEL 1B configures the VCSEL of the second group having a long distance from the anode power supply pad 102. More specifically, as illustrated in FIG. 1, among the twenty VCSELs in the Y direction, the first group of VCSELs, including the 1st to 6th VCSELs closer to the anode power supply pad 102, includes the VCSEL 1A. The second group of VCSELs, including the remaining 6th to 20th VCSELs, includes the VCSEL 1B.

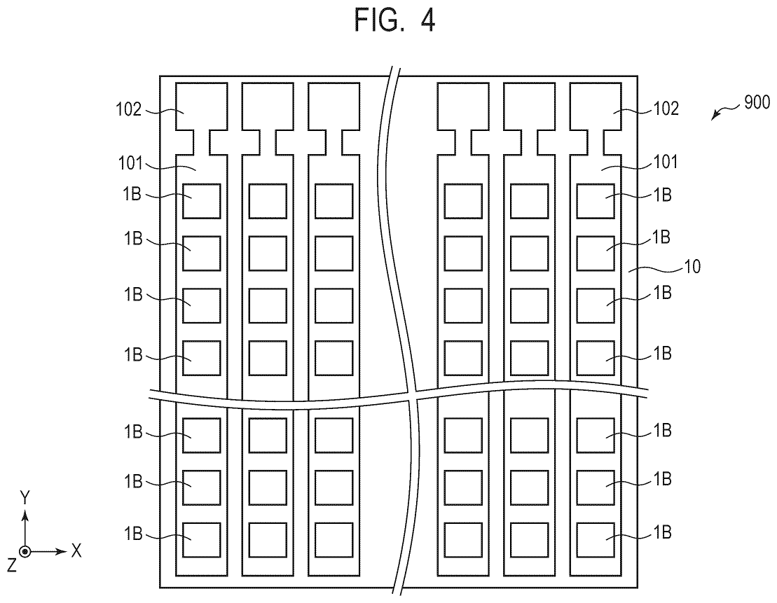

FIG. 4 is a plan view illustrating a configuration example of a VCSEL array 900 according to a comparative example. In the VCSEL array 900 according to the comparative example, as illustrated in FIG. 4, all the VCSELs (four hundred VCSELs) are the VCSELs 1B and arranged in an array. In the VCSEL array 900 according to the comparative example, in the case where the VCSELs 1B are arranged at a high density with a narrow interval between the VCSELs 1B due to a reduction in chip size or the like, it is difficult to thicken the wire for supplying power to each VCSEL 1B. Therefore, the VCSEL 1B located far from the anode power supply pad 102 and having a long current path has a larger voltage drop due to the wire resistance than that of the VCSEL 1B located near the anode power supply pad 102. Therefore, the voltage applied between an anode and a cathode of the VCSEL 1B decreases, and as a result, the amount of current injected decreases.

Then, the non-uniformity of the current injected into each VCSELs 1B of the VCSEL array 900 causes various adverse effects. For example, in order to cause a predetermined current to flow through the VCSEL 1B having the smallest current, input power increases, and the intensity of light of each VCSEL 1B varies in the VCSEL array 900. As a result, a signal of a dark image detected by a distance measurement device becomes weak, and therefore, a ratio between the signal and a noise in a light receiving unit becomes small, and the distance measurement accuracy varies, and in the case of an illumination application, various adverse effects such as an influence on in-plane illuminance unevenness occur.

In contrast, in the VCSEL array 100 according to the first embodiment, the VCSEL 1A of the first group having a high resistance value is disposed closer to the anode power supply pad 102 than the VCSEL 1B of the second group having a low resistance value. In other words, a current path from the anode power supply pad 102 to the VCSEL 1A having the high resistance value is shorter than a current path from the anode power supply pad 102 to the VCSEL 1B having a low resistance value. With this configuration, the resistance values of the VCSELs 1A and 1B including the resistance value of the anode wire 101 can be brought close to each other. Thus, even if a voltage drop occurs due to wire resistance, the current injected into the VCSELs 1A and 1B can be made more uniform, and a current distribution can be smoothed. Here, the current distribution represents distribution of a value of the current injected into each VCSEL in the VCSEL array. Since the current distribution can be smoothed, variations of light amount of the VCSELs 1A and 1B can be suppressed, and thus uniformity of the light emission in the VCSELs 1A and 1B can be improved. Due to the uniformity of light emission by the VCSELs 1A and 1B, variations in lifetime of the VCSELs 1A and 1B are also suppressed. Further, since the current distribution is smoothed, input power to the VCSEL array 100 is reduced. As described above, the effect of the decrease in the input power due to smoothing the current distribution is greater than the effect of the increase in the input power due to the increase in some of the resistors.

Further, since the heat generation amount of the VCSEL array 100 is proportional to the product of the power of resistance and the square of current value, the effect of reducing the current value due to smoothing the current distribution is significant from perspective of the heat generation as well.

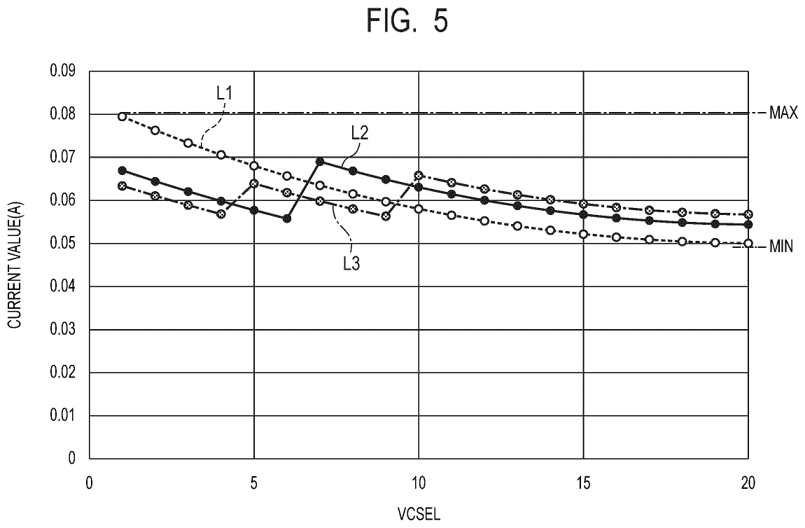

FIG. 5 is a graph illustrating a current distribution in each VCSEL array. In FIG. 5, a vertical axis represents current value, and a horizontal axis represents n-th VCSEL counted from the side closer to the anode power supply pad 102 in one array (twenty VCSELs 1 in one column). FIG. 5 illustrates a current distribution L2 of one array in the VCSEL array 100 according to the first embodiment. FIG. 5 also illustrates a current distribution L1 of one array in the VCSEL array 900 according to the comparative example.

In the VCSEL array 900 according to the comparative example, a ratio between a maximum value MAX and a minimum value MIN of current flowing through each VCSEL 1B of one array is 0.63 (current distribution L1 in FIG. 5). Further, in the VCSEL array 900, when the minimum current value necessary for one VCSEL 1B is 0.06 A, the current value necessary for one array is estimated to be 1.44 A in consideration of variation in the current value, and the input power is 7.29 W. On the other hand, in the VCSEL array 100 according to the first embodiment, a ratio between a maximum value and a minimum value of current flowing through the VCSELs 1A and 1B of one array is 0.76 (current distribution L2 in FIG. 5). Further, in the VCSEL array 100, when the minimum current value required for one VCSEL 1A or 1B is 0.06 A, the current value required for one array is estimated to be 1.33 A in consideration of the variation in the current value, and the input power is 6.70 W. As described above, in the VCSEL array 100, since the ratio of the maximum value to the minimum value is close to 1.0 as compared with the VCSEL array 900 according to the comparative example, the current distribution can be smoothed. In addition, the VCSEL array 100 can reduce the current value required for one array and suppress the input power, as compared with the VCSEL array 900 according to the comparative example.

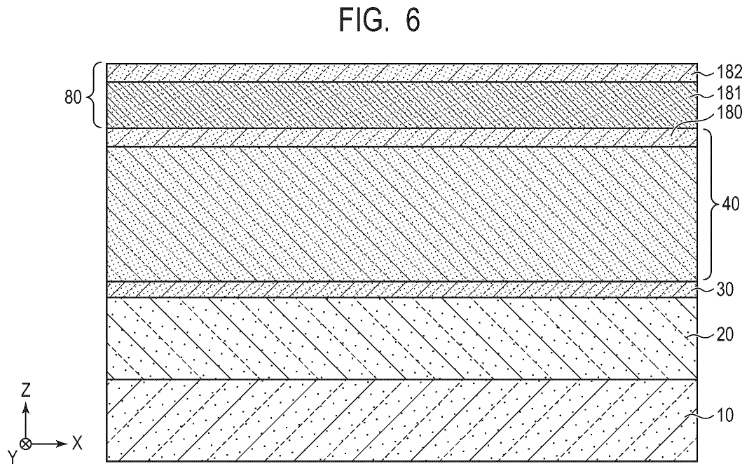

Next, a method of manufacturing the VCSEL array 100 including the two types of VCSELs 1A and 1B will be described. FIG. 6 is a cross-sectional view illustrating a configuration example of an epitaxial wafer including an epitaxial growth portion. As illustrated in FIG. 6, first, the first DBR 20, the semiconductor resonator 30, the second DBR 40, an AlInP resistance layer 181 forming the semiconductor layer 80, and a second p-type GaAs contact layer 182 are sequentially epitaxially grown on the n-type GaAs substrate 10. The uppermost layer of the second DBR 40 is the first p-type GaAs contact layer 180.

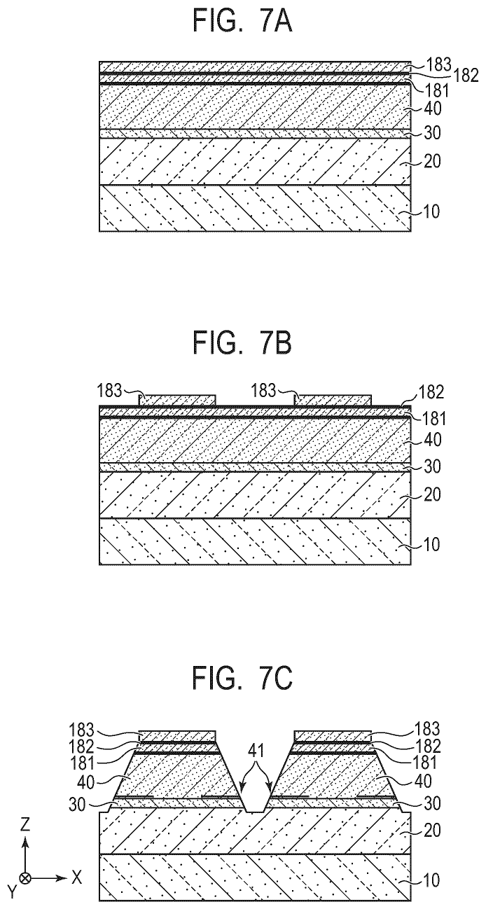

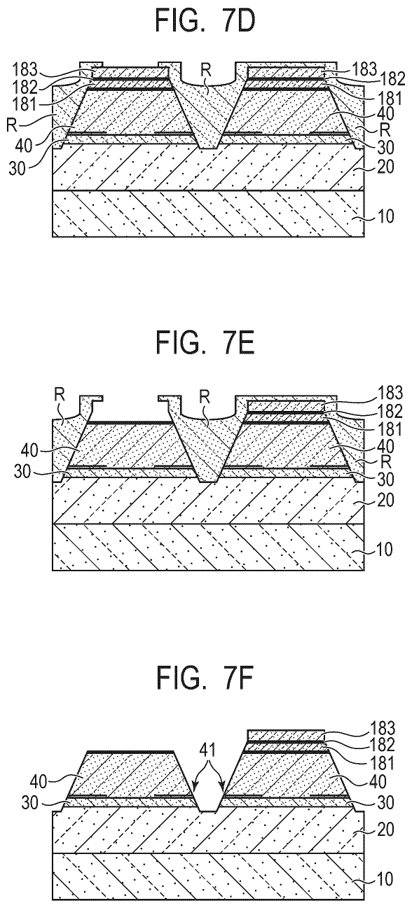

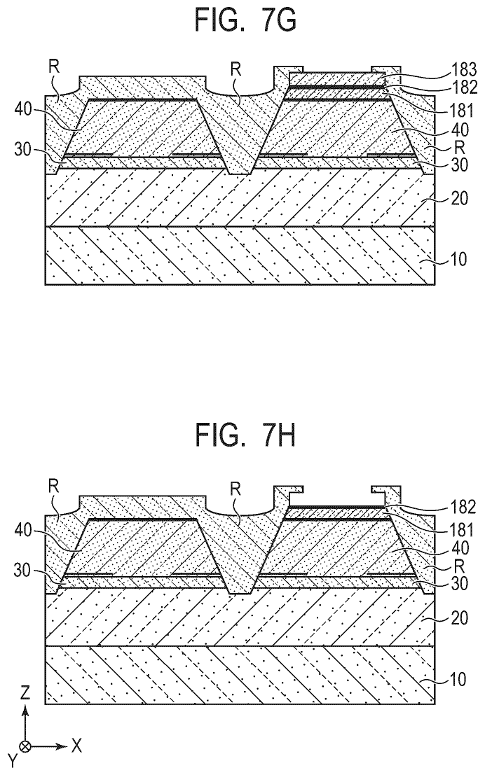

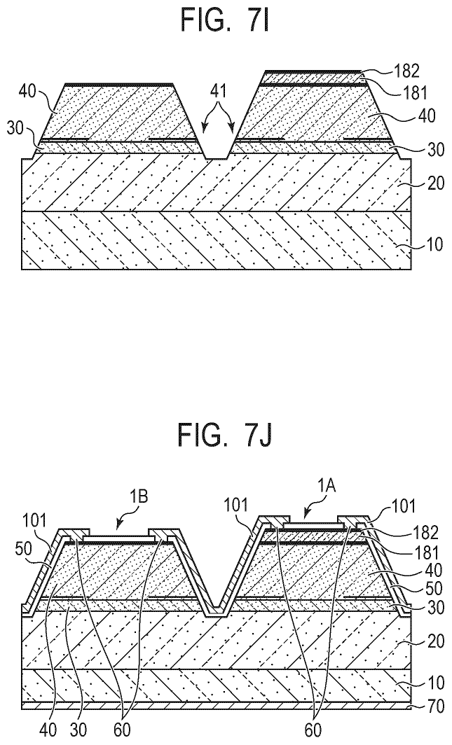

Next, a manufacturing process will be described with reference to FIGS. 7A to 7J. FIGS. 7A to 7J illustrate cross sections of the two VCSELs 1A and 1B by excerpting portions in which the VCSEL 1A and the VCSEL 1B are disposed adjacent to each other in the Y direction in FIG. 1, but other portions can be formed by the same manufacturing process.

First, an SiOx layer 183 serving as a hard mask during dry etching is formed on the second p-type GaAs contact layer 182 by plasma CVD (FIG. 7A).

Next, the SiOx layer 183 is patterned by photolithography and wet etching. This pattern serves as a hard mask during dry etching (FIG. 7B).

Next, a mesa structure is formed by dry etching. When the mesa structure is formed, the second DBR 40 including the second p-type GaAs contact layer 182, the AlInP resistance layer 181, and the first p-type GaAs contact layer 180 is etched. Further, the semiconductor resonator 30 is etched, and a part of the first DBR 20 is also etched. When it is desired to dispose the VCSEL 1 at a high density, it is desirable to make sidewall angle of the mesa structure close to perpendicular to the n-type GaAs substrate 10. On the other hand, in a film formed on the side wall of the mesa structure, such as the insulating film 50 and the anode wire 101, in the case where disconnection due to a mesa step adversely affects the device characteristics, the side wall angle is desirably smaller than perpendicular. Therefore, the sidewall angle is appropriately selected by changing etching conditions according to required specifications and performance.

Next, heat treatment is performed in a water vapor atmosphere to selectively oxidize a part of the second DBR 40 from the mesa sidewall, thereby forming the current confinement layer 41 (FIG. 7C).

Next, a resist R including a resist opening is formed on the VCSEL 1B by photolithography, and the SiOx layer 183 on the VCSEL 1B is selectively exposed (FIG. 7D).

Next, the SiOx layer 183 in a region including the resist opening is selectively etched by wet etching using buffered hydrofluoric acid. Further, the second p-type GaAs contact layer 182 is selectively etched with a citric acid-based etchant, and then the AlInP resistance layer 181 is selectively etched with a hydrochloric acid-based etchant (FIG. 7E). Thereafter, a resist pattern is removed once (FIG. 7F).

Next, the resist R including the resist opening is formed on the VCSEL 1A by photolithography, and the SiOx layer 183 on the VCSEL 1A is selectively exposed (FIG. 7G).

Next, the SiOx layer 183 in the region including the resist opening is selectively etched by wet etching using buffered hydrofluoric acid (FIG. 7H), and then the resist pattern is removed (FIG. 7I).

Next, the insulating film 50 is formed so as to cover the mesa structure, and an opening is formed in the insulating film 50 by the photolithography technique and the etching technique. The upper electrode 60 and the anode wire 101 are formed by the photolithography technique, a vacuum deposition technique, and a lift-off technique then an emission port is formed. Next, after polishing the back surface of the n-type GaAs substrate 10, the back electrode 70 is formed on a back surface side of the n-type GaAs substrate 10 (FIG. 7J).

By proceeding with the above steps, two types of VCSELs, i.e., the VCSEL 1A including the semiconductor layer 80 including the AlInP resistance layer 181 and the VCSEL 1B not including the semiconductor layer 80, can be manufactured.

In the present embodiment, an example in which the VCSEL 1B does not include the semiconductor layer 80 has been described, but the present invention is not limited thereto, and the current distribution can be improved as compared with the comparative example by changing the resistance values of the two types of the VCSELs 1A and 1B. Specifically, the VCSEL 1B may have the semiconductor layer 80 thinner than that of the VCSEL 1A. The same applies to the following embodiments.

In addition, in the present embodiment, an example in which the power supply pad 102 is provided at one end of the anode wire 101 in the Y direction has been described, but the present invention is not limited thereto, and the power supply pad 102 may be provided at both ends of the anode wire 101 in the Y direction. Even in this case, the VCSEL 1A and the VCSEL 1B are arranged in the same manner with respect to the power supply pad 102. Specifically, the VCSEL 1A may be disposed on the side close to the power supply pad 102, and the VCSEL 1B may be disposed on the side far from the power supply pad 102 (at the center of the array). The same applies to the following embodiments.

### Second Embodiment

Next, a VCSEL array 100A according to the second embodiment will be described. The VCSEL array 100A according to the second embodiment includes three types of VCSELs 1A, 1Aa, and 1B having different resistance values.

The VCSEL 1A, the VCSEL 1Aa, and the VCSEL 1B have different resistance values between the upper electrode 60 and the back electrode 70. A first resistance value between the upper electrode 60 and the back electrode 70 of the VCSEL 1A is denoted by R1, and a second resistance value between the upper electrode 60 and the back electrode 70 of the VCSEL 1B is denoted by R2. When a third resistance value between the upper electrode 60 and the back electrode 70 of the VCSEL 1Aa is R3, R1>R3>R2. That is, the resistance value of the VCSEL 1Aa is smaller than the resistance value of the VCSEL 1A and larger than the resistance value of the VCSEL 1B.

In the VCSEL 1Aa, the semiconductor layer 80 has a two-layer structure of an AlInP layer having a thickness of 0.25 μm and a carrier concentration of 1×10¹⁷ cm⁻³ and a GaAs contact layer having a thickness of 50 nm and a carrier concentration of 1×10¹⁹ cm⁻³ from the side close to the second DBR 40. An optical film thickness of the semiconductor layer 80 is kc. With this configuration, the resistance value of the VCSEL 1Aa is 1.2 times the resistance value of the VCSEL 1B. In the VCSEL 1A, the semiconductor layer 80 has a four-layer structure in which the AlInP layer and the GaAs contact layer similar to those of the semiconductor layer 80 of the VCSEL 1Aa are repeatedly stacked two times from the side close to the second DBR 40. The optical film thickness of the semiconductor layer 80 can be 2 λc. With this configuration, the resistance value of the VCSEL 1A is 1.4 times the resistance value of the VCSEL 1B.

The plurality of VCSELs 1 is divided into three groups (first to third groups) according to the distance from the anode power supply pad 102. The third group is disposed between the first group and the second group. The third group includes VCSEL 1Aa having the resistance value smaller than that of VCSEL 1A of the first group and larger than that of VCSEL 1B of the second group. As described above, the VCSEL array 100A is configured such that the VCSELs in the group closer to the anode power supply pad 102 have higher resistance values. That is, the VCSEL 1A of the first group, the VCSEL 1Aa of the third group, and the VCSEL 1B of the second group are arranged in this order from the anode power supply pad 102 in descending order of resistance value. Specifically, among the twenty VCSELs in the Y direction, the first group including the 1st to 4th VCSELs closest to the anode power supply pad 102 is configured by the VCSELs 1A with the highest resistance value. Furthermore, the third group including the 5th to 9th VCSELs is configured by the VCSELs 1Aa with the second highest resistance value, and the second group including the 10th to 20th VCSELs is configured by the VCSELs 1B with the lowest resistance value.

In the VCSEL array 100A, the ratio between the maximum value and the minimum value of the current flowing through the VCSELs 1A, 1Aa, and 1B is 0.86 (current distribution L3 in FIG. 5). As described above, the VCSEL array 100A according to the second embodiment can smooth the current distribution more than that of the VCSEL array 100 (current distribution L2 in FIG. 5) according to the first embodiment. In the VCSEL array 100A according to the second embodiment, the input power is 6.35 W when the minimum current value required for each VCSEL is 0.06 A. Accordingly, the VCSEL array 100A can reduce the input power as compared with the input power (6.70 W) of the VCSEL array 100 according to the first embodiment including two types of VCSELs.

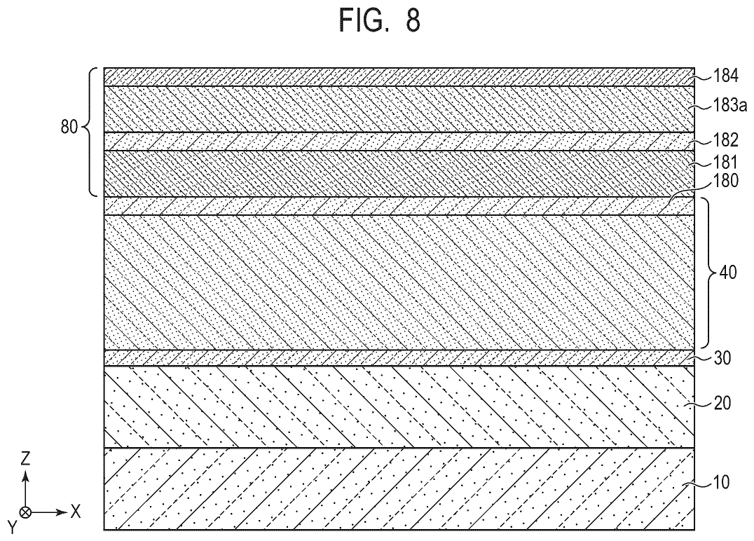

Next, a method of manufacturing the VCSEL array 100A including the three types of VCSELs 1A, 1Aa, and 1B according to the second embodiment will be described. In the second embodiment, as compared with the case of manufacturing the two types of VCSELs 1A and 1B according to the first embodiment, the semiconductor layer 80 has a four-layer structure at a stage of epitaxial growth. FIG. 8 is a cross-sectional view illustrating a configuration example of an epitaxial wafer including an epitaxial growth portion.

As illustrated in FIG. 8, as the semiconductor layer 80, the AlInP resistance layer 181, the second p-type GaAs contact layer 182, an AlInP resistance layer 183a, and a third p-type GaAs contact layer 184 are epitaxially grown in this order.

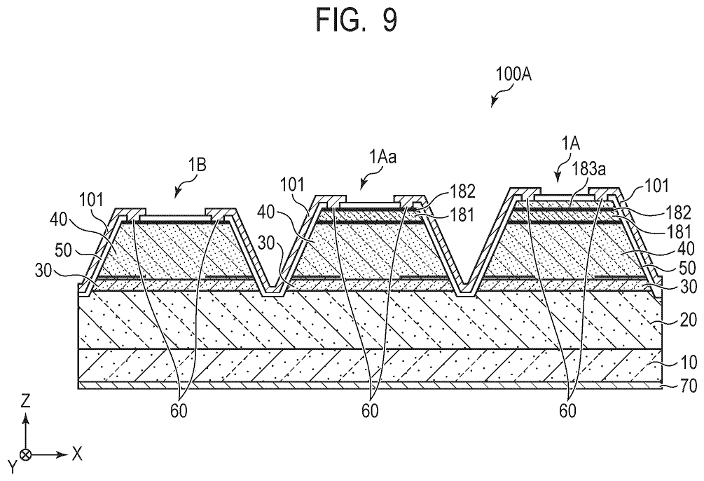

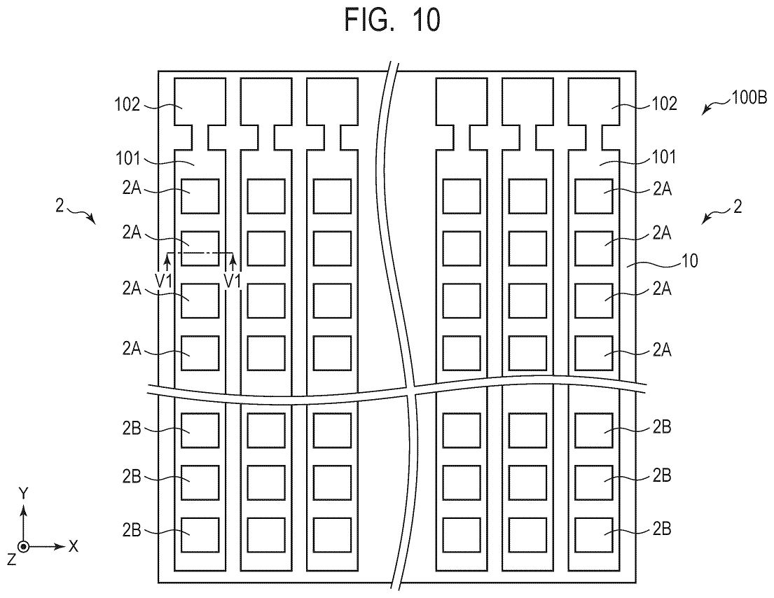

As illustrated in FIG. 9, in the VCSEL 1, the third p-type GaAs contact layer 184, the AlInP resistance layer 183a, the second p-type GaAs contact layer 182, and the AlInP resistance layer 181 are removed by etching. That is, with respect to the VCSEL 1i, the entire semiconductor layer 80 is removed. In the VCSEL 1Aa, the third p-type GaAs contact layer 184 and the AlInP resistance layer 183a are removed by etching, and the second p-type GaAs contact layer 182 and the AlInP resistance layer 181 are left. That is, a part of the semiconductor layer 80 is removed from the VCSEL 1Aa. In the VCSEL 1A, all the layers forming the semiconductor layer 80 are left. Thus, three types of VCSELs 1A, 1Aa, and 1B having different resistance values can be manufactured. In the second embodiment, the VCSELs 1A, 1Aa, and 1B are not arranged next to each other as illustrated in FIG. 9, but in FIG. 9, for the sake of convenience, the VCSELs of three types of resistors are illustrated side by side in order to explain the cross-sectional configuration.

### Third Embodiment

Next, a VCSEL array 100B according to a third embodiment will be described. FIG. 10 is a plan view illustrating a configuration example of the VCSEL array 100B according to the third embodiment. The VCSEL array 100B according to the third embodiment includes VCSELs 2A and 2B different from the VCSELs 1A and 1B according to the first embodiment. Hereinafter, the VCSELs 2A and 2B will be described in detail. In the following description, the same components as those of the VCSELs 1A and 1B according to the first embodiment are denoted by the same reference numerals, and detailed description thereof will be omitted.

For example, as illustrated in FIG. 10, the VCSEL array 100B includes a plurality of VCSELs 2, an anode wire 101, and an anode power supply pad 102. Note that FIG. 10 illustrates four VCSELs 2 on one side in the Y direction and three VCSELs 2 on the other side in the Y direction among the plurality of VCSELs 2 connected to each anode wire 101.

Twenty VCSELs 2 are arranged in one column in the Y direction, and twenty bundles of the twenty arrangements in the Y direction are arranged in the X direction. As a result, a total of four hundred (20×20) VCSELs 2 are arranged in an array and have a rectangular shape as a whole when viewed from the Z direction.

The plurality of anode wirings 101 are each provided extending in the Y direction and arranged side by side in the X direction. One anode wire 101 is electrically connected to twenty VCSELs 2 in the Y direction. Then, twenty such anode wires 101 are provided side by side in the X direction. Each anode wire 101 supplies current to twenty VCSELs 2 connected in parallel.

The VCSEL array 100B configured as described above can cause the four hundred VCSELs 2 to emit light by supplying current from an outside to the twenty anode power supply pads 102 via Au wires. By sequentially being supplied current from the outside to the twenty anode power supply pads 102, sequential driving in which each column emits light at different timings can be performed.

Here, the VCSEL array 100B according to the third embodiment includes the VCSELs 2A and 2B as the plurality of VCSELs 2. In the following description, the VCSEL 2A and the VCSEL 2B may be simply referred to as “VCSEL 2” when it is not necessary to distinguish them from each other.

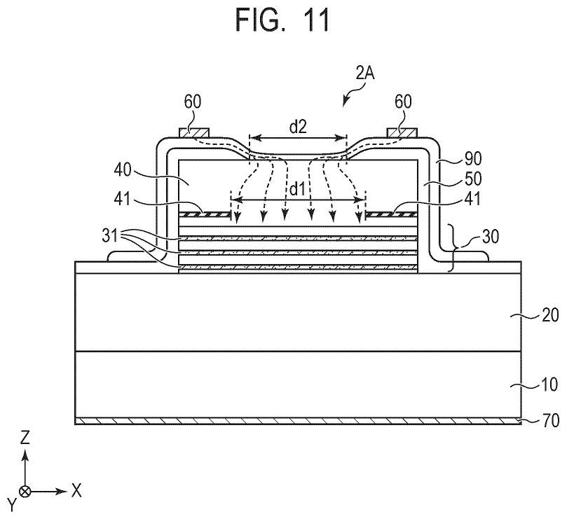

As illustrated in FIG. 11, the VCSEL 2A includes an n-type GaAs substrate 10, a first DBR 20, a semiconductor resonator 30, a second DBR 40, an insulating film 50, an upper electrode 60, and a back electrode 70. The VCSEL 2A further includes an ITO (Indium Tin Oxide) layer 90 as a transparent conductive film. The first DBR 20, the semiconductor resonator 30, the second DBR 40, the insulating film 50, the ITO layer 90, and the upper electrode 60 are stacked in this order on the first surface of the n-type GaAs substrate 10. The back electrode 70 is provided on a second surface opposite to a first surface of the n-type GaAs substrate 10. FIG. 11 is a cross-sectional view along line V1-V1 of FIG. 10. Although these members are in direct contact in the VCSEL 2A in FIG. 11, other members may be provided therebetween. In addition, the above description is a description representing a structure, and does not limit the order of manufacturing each member.

The semiconductor resonator 30 and the second DBR 40 are processed into a mesa shape, and the insulating film 50 is provided on a side surface and an upper surface of the mesa. Further, the ITO layer 90 is formed on the insulating film 50. That is, the ITO layer 90 covers the mesa-shaped semiconductor resonator 30 and the second DBR 40 from above the insulating film 50.

A central portion of the insulating film 50 is partially removed from the upper surface of the second DBR 40, and the ITO layer 90 is in contact with the upper surface of the second DBR 40 in the removed portion. The portion from which the insulating film 50 is removed is referred to as an “insulation opening”. The shape of the insulation opening is, for example, square, and the width of the insulation opening is represented by d2 (see FIG. 11). The ITO layer 90 is provided between the upper electrode 60 and the second DBR 40 and is in contact with the upper surface of the second DBR 40 in the insulation opening. The upper electrode 60 is in electrical contact with a part of the ITO layer 90. The optical film thickness of the ITO layer 90 is ½ λc.

The second DBR 40 has a GaAs contact layer (not illustrated) having a thickness of 50 nm and a carrier concentration of 1×10¹⁹ cm⁻³ in the uppermost layer and improves the electrical contact with the ITO layer 90.

In the third embodiment, the resistance value is changed by changing a contact area between the GaAs contact layer of the second DBR 40 and the ITO layer 90. Specifically, the contact area is changed by changing the width d2 of the insulation opening, and the amount of current flowing into the second DBR 40 is adjusted. For example, the contact area is reduced by relatively reducing the width d2 of the insulation opening, thereby increasing the resistance value, and reducing the amount of current flowing into the second DBR 40. On the other hand, by increasing the width d2 of the insulation opening relatively, the contact area is increased, whereby the resistance value is lowered and the amount of current flowing into the second DBR 40 is increased.

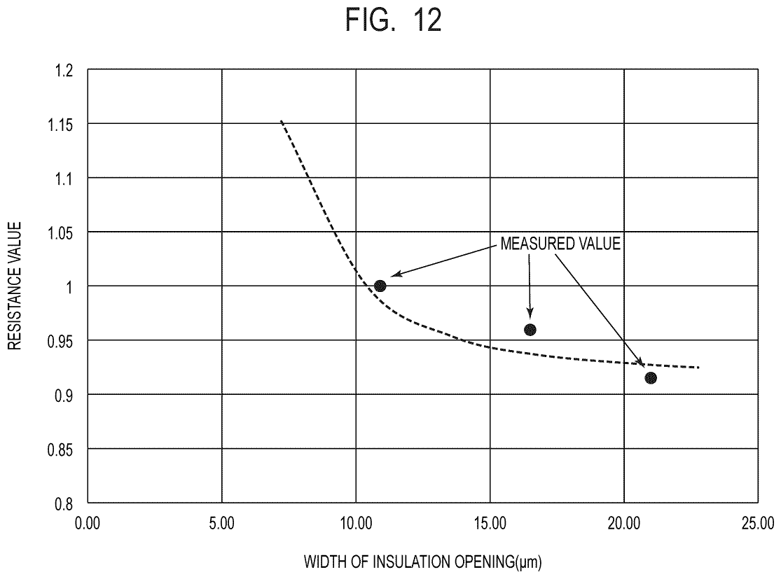

FIG. 12 is a graph illustrating a relationship between the width d2 of the insulation opening and the resistance value (a calculation result and an actual measurement value). In FIG. 12, a horizontal axis represents the width d2 of the insulation opening, and a vertical axis represents the relative resistance values, where the resistance value is 1.0 for the case when the width d2 of the insulation opening is 10.6 m. Here, as illustrated in FIG. 12, when d2=7.5 m, the resistance value is changed to 1.15 times, and when d2=20 m, the resistance value is changed to 0.93 times. Further, according to FIG. 12, it can be confirmed that the actual measurement value also follows the calculation result. When the insulation opening is located inside the non-oxidized region, the insulation opening may adversely affect the light emitted from the VCSEL 2A. When this is a problem, it is desirable that the width d2 of the insulation opening is larger than the width d1 of the non-oxidized region. The VCSEL 2B is configured in the same manner as the VCSEL 2A except that the width d2 of the insulation opening is different.

By adjusting the width d2 of the insulation opening of the VCSEL 2A, the contact area between the ITO layer 90 and the second DBR 40 in the VCSEL 2A is smaller than the contact area between the ITO layer 90 and the second DBR 40 in the VCSEL 2B. Thus, when a first resistance value between the upper electrode 60 and the back electrode 70 of the VCSEL 2A is R1 and a second resistance value between the upper electrode 60 and the back electrode 70 of the VCSEL 2B is R2, R1>R2. That is, the VCSEL 2A has a larger resistance value than that of the VCSEL 2B. For example, based on FIG. 12, the width d2 of the insulation opening of the VCSEL 2A can be 10.6 μm, and the width d2 of the insulation opening of the VCSEL 2B can be 16.8 μm. At this time, the width d1 of the non-oxidized region of the current confinement layer 41 can be 10.6 μm. With this design, the resistance value of the VCSEL 2A is about 1.07 times the resistance value of the VCSEL 2B.

In the VCSEL array 100B, the arrangement of the two types of VCSELs 2A and 2B having different resistance values is devised so that current injected into the VCSELs 2A and 2B are more uniform. Here, the plurality of VCSELs 2 is divided into two groups (first and second groups) according to the distance from the anode power supply pad 102. The VCSEL array 100B is configured such that the VCSELs in the group closer to the anode power supply pad 102 have higher resistance value. Specifically, the VCSEL 2A configures the VCSEL of the first group having a short distance from the anode power supply pad 102, and the VCSEL 2B configures the VCSEL of the second group having a long distance from the anode power supply pad 102. More specifically, as illustrated in FIG. 10, among the twenty VCSELs in the Y direction, the 1st to 5th VCSELs of the first group closer to the anode power supply pad 102 are configured by the VCSEL 2A having a large resistance value. The remaining 6th to 20th VCSELs of the second group are configured by VCSELs 2B having a small resistance value.

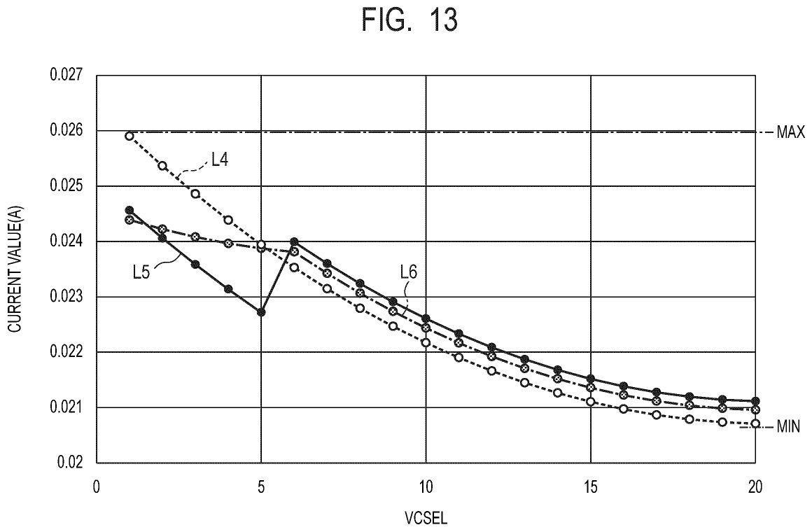

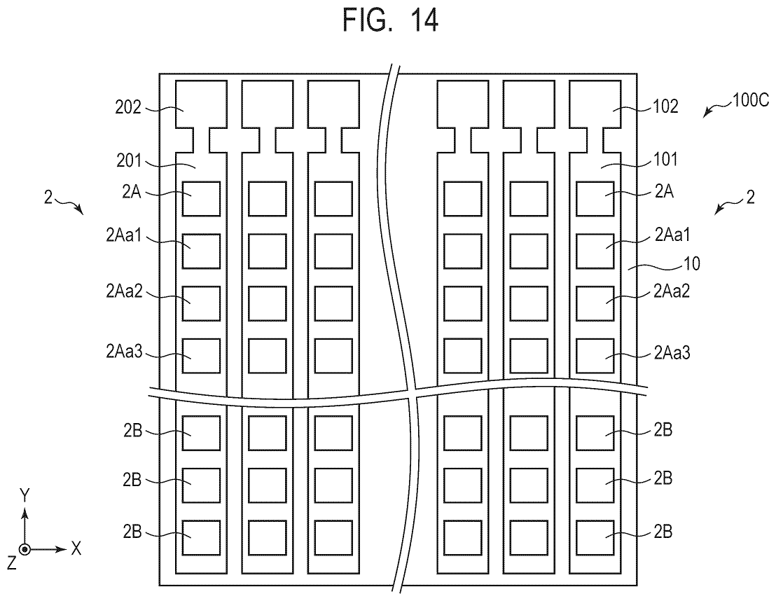

FIG. 13 is a graph illustrating a current distribution in each VCSEL array. In FIG. 13, a vertical axis represents current value, and a horizontal axis represents n-th VCSEL counted from the side closer to the anode power supply pad 102 in one array. FIG. 13 illustrates a current distribution L5 of one array in the VCSEL array 100B according to the third embodiment. FIG. 13 also illustrates a current distribution L4 of one array in the VCSEL array according to the comparative example. In the VCSEL array according to the comparative example, all the VCSELs (four hundred VCSELs) are the VCSEL 2Bs and arranged in an array.

In the VCSEL array according to the comparative example, a ratio between the maximum value MAX and the minimum value MIN of current flowing through each VCSEL 2B is 0.80 (current distribution L4 in FIG. 13). In contrast, in the VCSEL array 100B according to the third embodiment, a ratio between a maximum value and a minimum value of current flowing through the VCSELs 2A and 2B is 0.86 (current distribution L5 in FIG. 13). Accordingly, in the VCSEL array 100B, the ratio of the maximum value to the minimum value is close to 1.0 as compared with the VCSEL array 900 according to the comparative example, and this enables the current distribution to be smoothed. In addition, in the VCSEL array of the comparative example, the input power is 90.4 mW (0.49 A) when the injection current amount to one array is adjusted so that the lowest current density injected into each VCSEL 2B is 20 kA/cm² or more. In the VCSEL array 100B of the third embodiment, the input power is 90.2 mW (0.48 A) when the injection current amount to one array is adjusted so that the lowest current density injected into each of the VCSELs 2A and 2B is 20 kA/cm² or more. From this, it can be seen that the VCSEL array 100B of the third embodiment can also reduce the power input to the array.

The VCSEL array 100B is characterized in that a plurality of types of VCSELs 2 can be simultaneously realized only by changing the width d2 of the insulation opening on the photomask without increasing the number of epitaxial layers or the like as in the first embodiment. Therefore, in the VCSEL array 100B, the width d2 of the insulation opening may be increased without being limited to two types. On the other hand, in the VCSEL array 100B, since the changeable width of the width d2 of the insulation opening is limited as compared with the VCSEL array 100 of the first embodiment, the amount of change in the resistance value is small.

### Fourth Embodiment

Next, a VCSEL array 100C according to a fourth embodiment will be described. The VCSEL array 100C according to the fourth embodiment includes six types of VCSELs 2A, 2Aa1, 2Aa2, 2Aa3, 2Aa4, and 2B having different resistance values. When the current value rapidly changes at boundary between the VCSEL 2A and the VCSEL 2B as in the change in the current value (current distribution L5 in FIG. 13) of the VCSEL array 100B according to the third embodiment, the current distribution can be made gentler by finely setting the resistance value of each VCSEL 2. FIG. 14 is a plan view illustrating a configuration example of a VCSEL array 100C according to the fourth embodiment. The plurality of VCSELs 2 include six types of VCSELs 2 having different resistance values from each other, and are divided into six groups (first to sixth groups) according to the distance from the anode power supply pad 102. The VCSEL array 100C is configured such that the VCSELs in group closer to the anode power supply pad 102 have higher resistance values. Specifically, the VCSEL 2A of the first group, the VCSEL 2Aa1 of the second group, and the VCSEL 2Aa2 of the third group are arranged one by one in order from the side closer to the anode power supply pad 102. Then, following the VCSEL 2Aa2 of the third group, the VCSEL 2Aa3 of the fourth group and the VCSEL 2Aa4 of the fifth group (not illustrated) are configured, and the 6th to 20th VCSELs are configured by the VCSEL 2B of the sixth group.

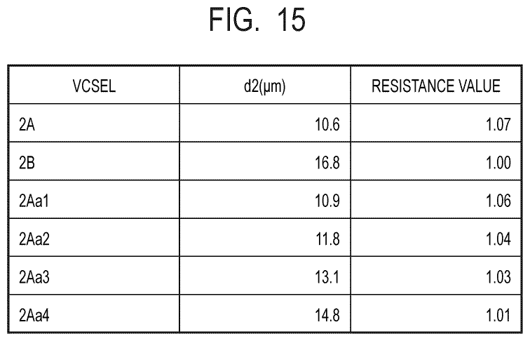

In the VCSEL array 100C according to the fourth embodiment, as illustrated in FIG. 15, the width d2 of the insulation opening is in a relationship of VCSEL 2B>VCSEL 2Aa4>VCSEL 2Aa3>VCSEL 2Aa2>VCSEL 2Aa1>VCSEL 2A. That is, the width d2 of the insulation opening becomes smaller as it is closer to the anode power supply pad 102. Therefore, the resistance value becomes a relationship of VCSEL 2A>VCSEL 2Aa1>VCSEL 2Aa2>VCSEL 2Aa3>VCSEL 2Aa4>VCSEL 2B, and the resistance value of the VCSEL of the group closer to the anode power supply pad 102 becomes large. This enables the resistance value of each VCSEL 2 to be finely adjusted in stages. As a result, as compared with the VCSEL array 100B (current distribution L5 in FIG. 13), the VCSEL array 100C can reduce the ratio between the maximum value and the minimum value of the current flowing through each VCSEL 2, and can further smooth the current distribution (current distribution L6 in FIG. 13).

### Fifth Embodiment

Next, a VCSEL array 100D according to a fifth embodiment will be described. The VCSEL array 100D has short high peak value pulse characteristics suitable for LiDAR. A configuration using a saturable absorption layer or the like (Hereinafter, it is also referred to as “high peak value VCSEL”.) is known. The problem peculiar to the high peak value VCSEL can be solved by combining the configuration of the high peak value VCSEL with the configuration of making the current value more uniform.

The high peak value VCSEL is characterized in that it can output a light pulse having a pulse width of about several 100 ps and a high peak value at the start of oscillation, and this is effective in improving the ranging distance and ranging accuracy of the LiDAR system.

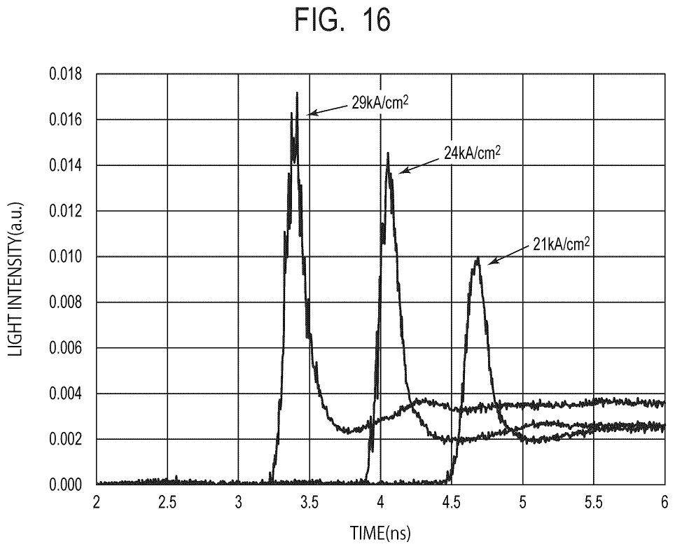

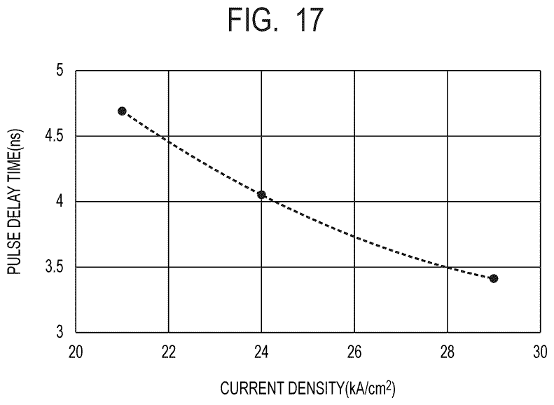

On the other hand, the high peak value VCSEL is characterized in that the timing at which a pulse is generated at the start of oscillation varies depending on the current density. FIG. 16 is a graph illustrating a relationship between current density and pulse generation timing. In FIG. 16, a vertical axis represents light intensity, and a horizontal axis represents time. FIG. 17 is a graph illustrating a relationship between current density and pulse delay time. In FIG. 17, a vertical axis represents pulse delay time, and a horizontal axis represents current density. As illustrated in FIGS. 16 and 17, the pulse generation timing shift of 1.27 ns occurs at the current density of 21 to 29 kA/cm².

Therefore, when a plurality of high peak value VCSELs is arrayed, when the current injected into the respective high peak value VCSELs become non-uniform, the light emission timings of the respective high peak value VCSELs differ. Therefore, the temporal change of the light intensity of the entire array becomes wider than the pulse width of the high peak value VCSEL, and there arises a problem that the merit of the LiDAR system is reduced.

Therefore, making the current more uniform enables the suppression of oscillation start timing deviation in the VCSEL array when the high peak value VCSELs are arrayed. In addition, it is possible to suppress an increase in the width of the light pulse when the light from each VCSEL is combined through optical systems or the like.

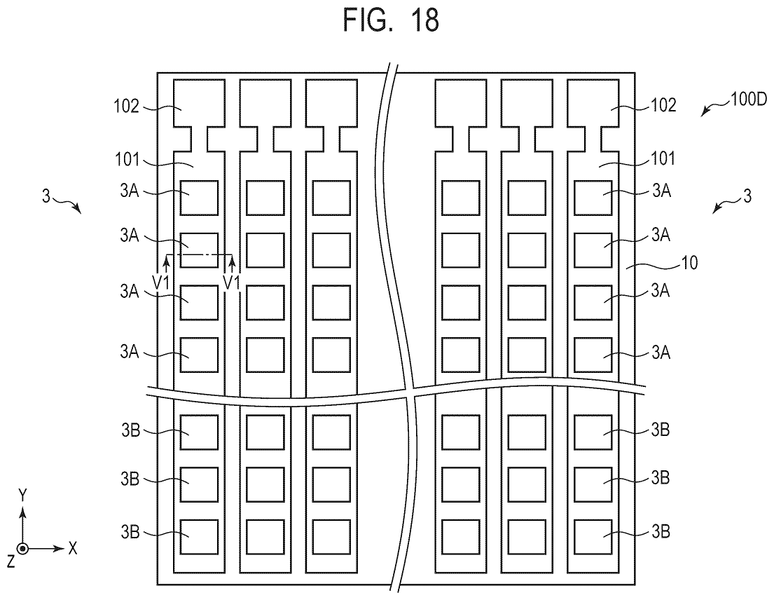

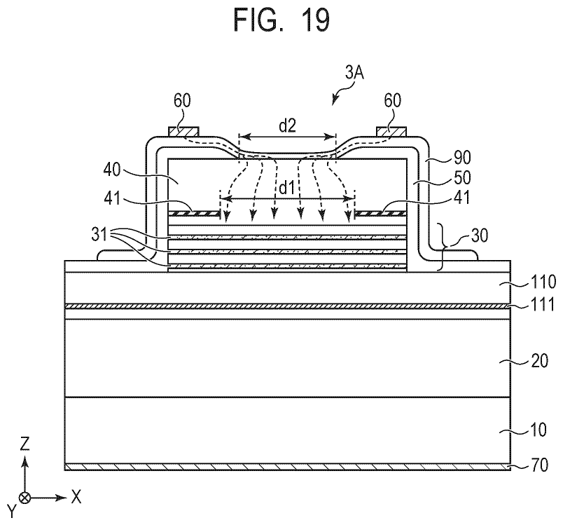

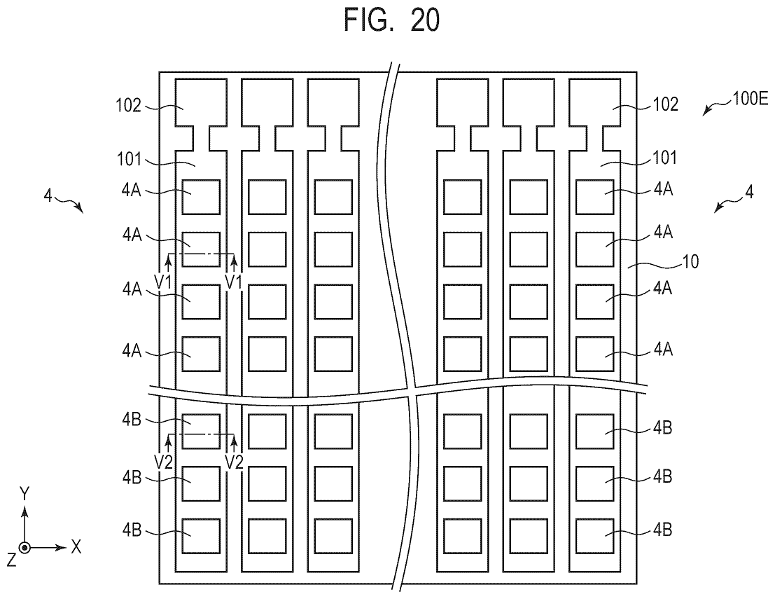

FIG. 19 is a cross-sectional view illustrating a configuration example of a high peak value VCSEL 3A according to the fifth embodiment, and is, for example, a V1-V1 cross-sectional view of FIG. 18. In the high peak value VCSEL 3A according to the fifth embodiment, the same components as those of the VCSEL 2A according to the fourth embodiment are denoted by the same reference numerals, and detailed description thereof will be omitted. The high peak VCSEL 3A is different from the VCSEL 2A in that barrier layers sandwiching a quantum well layer 31 are configured by GaAs layers. Furthermore, the high peak VCSEL 3A differs from the VCSEL 2A in that it has a spacer layer 110 that includes a saturable absorption layer 111. The spacer layer 110 is provided in the first DBR 20 (in the first reflector). With this configuration, the high peak value VCSEL 3A can emit an optical pulse having a short high peak value. In the fifth embodiment, the width d2 of the insulation opening of the high peak value VCSEL 3A is 10.4 m, and the width d2 of the insulation opening of the high peak value VCSEL 3B is 16.8 m. As a result, the high peak value VCSEL 3A has a higher resistance value than that of the high peak value VCSEL 3B.

FIG. 18 is a plan view illustrating a configuration example of a VCSEL array 100D according to the fifth embodiment. A plurality of VCSELs 3 is divided into two groups (first and second groups) according to the distance from the anode power supply pad 102. The VCSEL array 100D is configured such that the VCSELs in group closer to the anode power supply pad 102 have higher resistance values. Specifically, the VCSEL of the first group having a short distance from the anode power supply pad 102 is configured with the high peak value VCSEL 3A, and the VCSEL of the second group having a long distance from the anode power supply pad 102 is configured with the high peak value VCSEL 3B. More specifically, the VCSELs of the first group of the 1st to 5th VCSELs closer to the anode power supply pad 102 are configured with the high peak value VCSEL 3A, and the VCSELs of the second group of the remaining sixth to 20th VCSELs are configured with the high peak value VCSEL 3B.

With this configuration, the current injected into the high peak value VCSELs 3A and 3B can be made more uniform, and the deviation of the light emission timings of the high peak value VCSELs 3A and 3B can be suppressed. By arraying, the optical output can be increased, and a pulse having a high peak value of about a few 100 ps generated by the high peak value VCSELs 3A and 3B can be appropriately used. Here, the current value injected into one array is adjusted so that the minimum current density becomes 20 kA/cm² or more. In this case, in the comparative example in which one array is configured with all the same high peak value VCSELs 3B, the maximum current density is 25.1 kA/cm², and the pulse delay time difference in one array is 1.07 ns. In contrast, in the VCSEL array 100D according to the fifth embodiment, since one array is configured by the high peak value VCSELs 3A and 3B, the maximum current density is 23.3 kA/cm², and the pulse delay time difference in one array can be suppressed to 0.76 ns.

### Sixth Embodiment

Next, a VCSEL array 100E according to a sixth embodiment will be described. FIG. 20 is a plan view illustrating a configuration example of a VCSEL array 100E according to the sixth embodiment. The VCSEL array 100E according to the sixth embodiment includes VCSELs 4A and 4B different from the VCSELs 1A and the like according to the first to fifth embodiments. Hereinafter, the VCSELs 4A and 4B will be described in detail. In the following description, the same components as those of the VCSEL 1A and the like according to the first to fifth embodiments are denoted by the same reference numerals, and detailed description thereof will be omitted.

For example, as illustrated in FIG. 20, the VCSEL array 100E includes a plurality of VCSELs 4, an anode wire 101, and an anode power supply pad 102. Note that FIG. 20 illustrates four VCSELs 4 on one side in the Y direction and three VCSELs 4 on the other side in the Y direction among the plurality of VCSELs 4 connected to each anode wire 101.

Twenty VCSELs 4 are arranged in one column in the Y direction, and twenty bundles of the twenty arrangements in the Y direction are arranged in the X direction. As a result, a total of four hundred (20×20) VCSELs 4 are arranged in an array, and are formed in a rectangular shape as a whole when viewed from the Z direction.

The anode wires 101 extend in the Y direction and are arranged in the X direction. One anode wire 101 is electrically connected to twenty VCSELs 4 in the Y direction. Then, twenty such anode wires 101 are provided side by side in the X direction. Each anode wire 101 supplies current to twenty VCSELs 4 connected in parallel.

The VCSEL array 100B configured as described above can cause the four hundred VCSELs 4 to emit light by being supplied current from the outside to the twenty anode power supply pads 102 via Au wires. By sequentially being supplied current from the outside to the twenty anode power supply pads 102, sequential driving in which each column emits light at different timings can be performed.

Here, the VCSEL array 100E according to the sixth embodiment includes VCSELs 4A and 4B as the plurality of VCSELs 4. In the following description, the VCSEL 4A and the VCSEL 4B may be simply referred to as “VCSEL 4” when it is not necessary to distinguish them from each other.

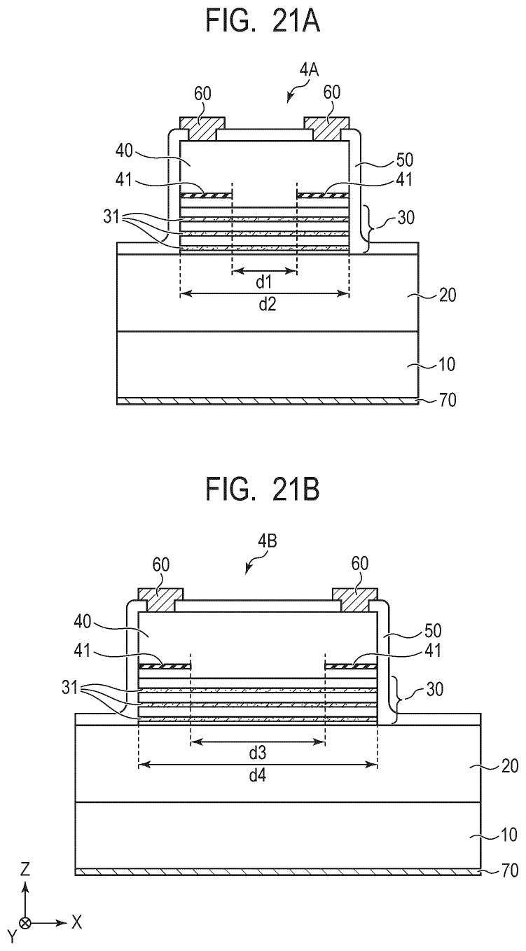

As illustrated in FIG. 21B, the VCSEL 4B includes an n-type GaAs substrate 10, a first DBR 20, a semiconductor resonator 30, a second DBR 40, an insulating film 50, an upper electrode 60, and a back electrode 70. The first DBR 20, the semiconductor resonator 30, the second DBR 40, and the upper electrode 60 are stacked in this order on the first surface of the n-type GaAs substrate 10. The back electrode 70 is provided on a second surface opposite to the first surface of the n-type GaAs substrate 10. In the VCSEL 4B, the semiconductor resonator 30 and the second DBR 40 are processed into a mesa shape. Although these members are in direct contact with each other in FIG. 21B, other members may be provided therebetween in the VCSEL 4B. In addition, the above description is a description representing a structure, and does not limit the order of manufacturing each member. FIG. 21B is a cross-sectional view along line V2-V2 of FIG. 20.

Next, the VCSEL 4A will be described. The VCSEL 4A is configured similarly to the VCSEL 4B described above. That is, as illustrated in FIG. 21A, the VCSEL 4A includes an n-type GaAs substrate 10, a first DBR 20, a semiconductor resonator 30, a second DBR 40, an insulating film 50, an upper electrode 60, and a back electrode 70. The first DBR 20, the semiconductor resonator 30, the second DBR 40, and the upper electrode 60 are stacked in this order on the first surface of the n-type GaAs substrate 10. The back electrode 70 is provided on a second surface opposite to the first surface of the n-type GaAs substrate 10. In the VCSEL 4A, the semiconductor resonator 30 and the second DBR 40 are processed into a mesa shape. FIG. 21A is a cross-sectional view along line V1-V1 of FIG. 20.

The size of the mesa of the VCSEL 4A is smaller than the size of the mesa of the VCSEL 4B. That is, the width d2 of the mesa of the VCSEL 4A is narrower than the width d4 of the mesa of the VCSEL 4B. Thus, as illustrated in FIG. 21A, the width d1 of the non-oxidized region of the current confinement layer 41 of the VCSEL 4A is narrower than the width d3 of the non-oxidized region of the current confinement layer 41 of the VCSEL 4B. This is because when oxidation is performed in the same manner on the same wafer, the oxidation distance from the mesa end becomes substantially the same. Since the current path in the mesa is narrowed by the non-oxidized region of the current confinement layer 41, the current path can be narrowed by making the non-oxidized region of the VCSEL 4A smaller than that of the VCSEL 4B, and the resistance value of the VCSEL 4A can be made larger than that of the VCSEL 4B.

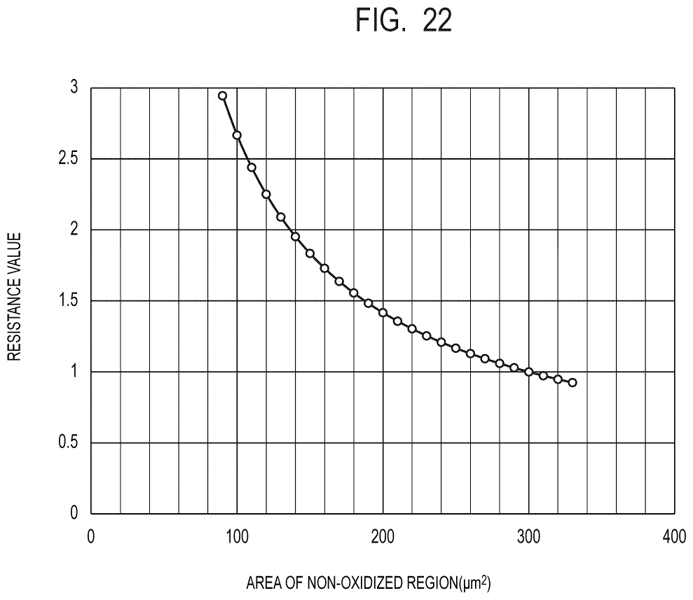

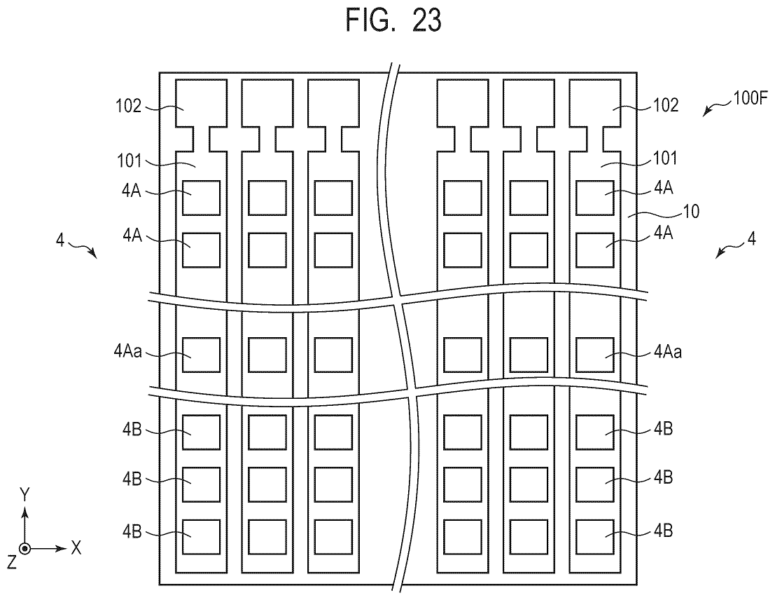

FIG. 22 is a graph illustrating a relationship between the area of the non-oxidized region of the current confinement layer 41 and the resistance value. In FIG. 22, a horizontal axis indicates the area of the non-oxidized region of the current confinement layer 41, and a vertical axis indicates relative resistance values, where the resistance value can be 1.0 for the case when the non-oxidized region of the current confinement layer 41 is 300 μm². The width d3 of the non-oxidized region of the VCSEL 4B is 17.3 μm, that is, the area of the non-oxidized region is approximately 300 μm², and the width d1 of the non-oxidized region of the VCSEL 4A is 15.1 μm, that is, the area of the non-oxidized region is approximately 227 μm². In this case, the resistance value of the VCSEL 4A is 1.27 times the resistance value of the VCSEL 4B.

The plurality of VCSELs 4 is divided into two groups (first and second groups) according to the distance from the anode power supply pad 102. The VCSEL array 100E is configured such that the VCSELs in group closer to the anode power supply pad 102 have higher resistance values. Specifically, the VCSEL 4A configures the VCSEL of the first group having a short distance from the anode power supply pad 102, and the VCSEL 4B configures the VCSEL of the second group having a long distance from the anode power supply pad 102. More specifically, as illustrated in FIG. 20, the 1st to 7th VCSELs of the first group closer to the anode power supply pad 102 are configured by the VCSEL 4A having a large resistance value. The remaining 8th to 20th VCSELs of the second group are configured by the VCSEL 4B having a small resistance value.

With this configuration, the current distribution of the VCSEL array 100E becomes similar to the current distribution L2 illustrated in FIG. 5. The current distribution of the VCSEL array 100E can be smoothed as compared with the case where the array is configured by the VCSEL 4Bs as in the comparative example (current distribution L1 illustrated in FIG. 5). In addition, by smoothing the current distribution, the amount of current necessary for the VCSEL array 100E can be reduced, and the input power can also be reduced.

### Seventh Embodiment

Next, a VCSEL array 100F according to a seventh embodiment will be described. As illustrated in FIG. 23, the VCSEL array 100F according to the seventh embodiment includes three types of VCSELs 4A, 4Aa, and 4B having different resistance values.

In the seventh embodiment, the width of the non-oxidized region of the VCSEL 4B is 17.3 μm, and the area of the non-oxidized region is 300 μm². The width of the non-oxidized region of the VCSEL 4A is 14.2 m, and the area of the non-oxidized region is 203 μm². The width of the non-oxidized region of the VCSEL 4Aa is 15.8 μm, and the area of the non-oxidized region is 250 μm². Accordingly, the resistance value of the VCSEL 4A becomes 1.40 times the resistance value of the VCSEL 4B, and the resistance value of the VCSEL 4Aa becomes 1.17 times the resistance value of the VCSEL 4B.

The plurality of VCSELs 4 is divided into three groups (first to third groups) according to the distance from the anode power supply pad 102. The VCSEL array 100F is configured such that the VCSELs in group closer to the anode power supply pad 102 have higher resistance values. Specifically, as illustrated in FIG. 23, the 1st to 4th VCSELs of the first groups closer to the anode power supply pad 102 are configured by the VCSEL 4A having the largest resistance value. The 5th to 9th VCSELs of the third group are configured by the VCSEL 4Aa having the next largest resistance value, and the 10th to 20th VCSELs of the second group are configured by the VCSEL 4B having the smallest resistance value.

In this case, the current distribution of the VCSEL array 100F according to the seventh embodiment has substantially the same tendency as the current distribution L3 (see FIG. 5). As in the comparative example, the current distribution of the VCSEL array 100F can be smoothed as compared with the case where the array is configured by the VCSELs 4B (current distribution L1 in FIG. 5). In addition, by smoothing the current distribution, the amount of current necessary for the VCSEL array 100F is reduced, and the input power is also reduced. As described above, in the VCSEL array 100F, by increasing the types of the resistance values of the VCSELs and appropriately setting the magnifications and arrangements of the respective resistance values, this enables the current distribution to be smoothed and the input power to be reduced.

### Eighth Embodiment

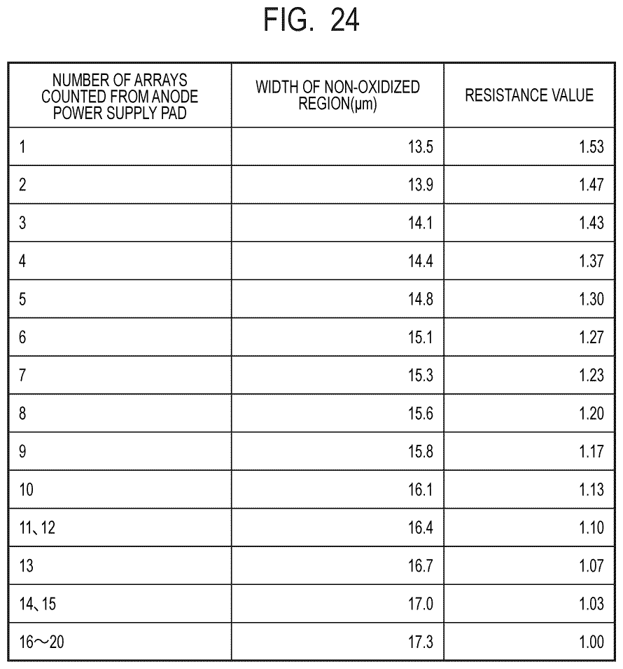

Next, a VCSEL array (not illustrated) according to the eighth embodiment will be described. The VCSEL array according to the eighth embodiment has a configuration in which the width of the non-oxidized region of the VCSEL 4 is set in more stages and the resistance value of the VCSEL 4 is changed in stages. FIG. 24 is a table illustrating a relationship between a non-oxidized region and a resistance value of each VCSEL 4. The plurality of VCSELs 4 is divided into 14 groups (first to fourteenth groups) according to the distance from the anode power supply pad 102. The VCSEL array is configured such that the VCSELs in group closer to the anode power supply pad 102 have higher resistance values. Specifically, as illustrated in FIG. 24, 14 types of VCSELs 4 are arranged for each group so that the resistance value of the VCSEL 4 gradually increases toward the anode power supply pad 102. In the VCSEL array, for example, the maximum magnification of the resistance value can be 1.53 times, and the width of the non-oxidized region can be 13.5 m.

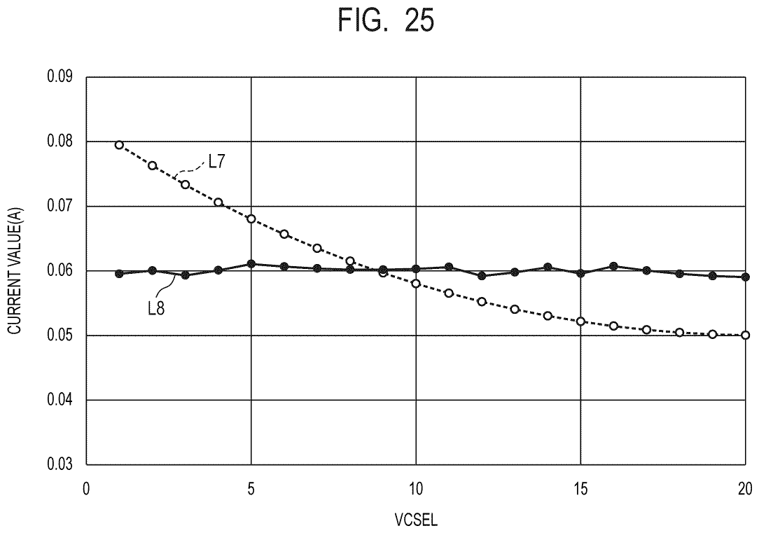

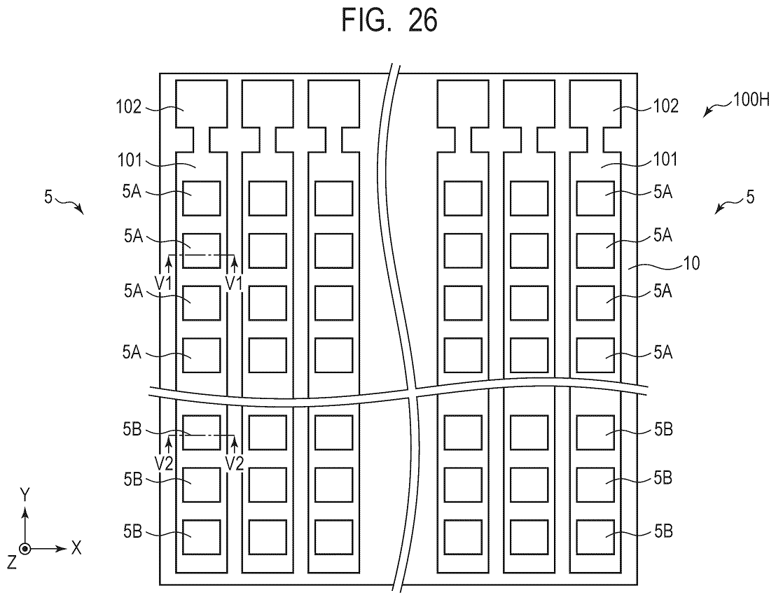

FIG. 25 is a graph illustrating a current distribution in the VCSEL array. FIG. 25 illustrates a current distribution L8 of one array in the VCSEL array according to the eighth embodiment. FIG. 25 also illustrates a current distribution L7 of one array in the VCSEL array according to the comparative example. In the VCSEL array according to the comparative example, all VCSELs (four hundred VCSELs) are the VCSELs 4 and arranged in an array. As illustrated in FIG. 25, the ratio of the maximum value and the minimum value of the current flowing through each VCSEL 4 of the VCSEL array is 0.97 (current distribution L8 in FIG. 25), which indicates that the current distribution can be smoothed as compared with the VCSEL array (current distribution L7 in FIG. 25) according to the comparative example.

Furthermore, according to the VCSEL array, various types of VCSELs can be simultaneously manufactured by simply changing the width of the mesa of the VCSEL 4 on the photomask in the manufacturing process. Further, as compared with the amount of change in the resistance value of the VCSEL array 100B of the third embodiment, the amount of change in the resistance value of the VCSEL array can be increased. In the VCSEL array, by appropriately increasing the types of resistance values as compared with the example illustrated in FIG. 24, this enables bringing the ratio between the maximum value and the minimum value closer to 1.

Since the VCSEL array changes the width of the non-oxidized region, an oscillation mode, FFP (Far Field Pattern), and current density distribution may affect the assumed use conditions. In such a case, it is desirable to employ a method in which a change in the non-oxidized region is suppressed to be small by combining with other embodiments. In this case, it is conceivable to define the resistance value of the VCSEL based on the current value actually applied to the VCSEL, instead of defining the resistance value based on the length of the current path from the anode power supply pad 102. Specifically, by arranging a VCSEL having a high resistance value at a location having a high current value, the current distribution of the entire array can be made smoother.

### Ninth Embodiment

Next, a VCSEL array 100H according to a ninth embodiment will be described. FIG. 26 is a plan view illustrating a configuration example of a VCSEL array 100H according to the ninth embodiment. The VCSEL array 100H according to the ninth embodiment includes VCSELs 5A and 5B different from the VCSELs 1A and the like according to the first to eighth embodiments. Hereinafter, the VCSELs 5A and 5B will be described in detail. In the following description, the same components as those of the VCSEL 1A and the like according to the first to eighth embodiments are denoted by the same reference numerals, and detailed description thereof will be omitted.

For example, as illustrated in FIG. 26, the VCSEL array 100H includes a plurality of VCSELs 5, an anode wire 101, and an anode power supply pad 102. Note that FIG. 26 illustrates four VCSELs 5 on one side in the Y direction and three VCSELs 5 on the other side in the Y direction among the plurality of VCSELs 5 connected to each anode wire 101.

Twenty VCSELs 5 are arranged in one column in the Y direction, and twenty bundles of the twenty arrangements in the Y direction are arranged in the X direction. As a result, a total of four hundred (20×20) VCSELs 5 are arranged in an array and have a rectangular shape as a whole when viewed from the Z direction.

The anode wires 101 extend in the Y direction and are arranged in the X direction. One anode wire 101 is electrically connected to twenty VCSELs 5 in the Y direction. Then, twenty such anode wires 101 are provided side by side in the X direction. Each anode wire 101 supplies current to the twenty VCSELs 5 connected in parallel.

The VCSEL array 100H configured as described above can cause the four hundred VCSELs 5 to emit light by being supplied current from the outside to the twenty anode power supply pads 102 via Au wires. By sequentially being supplied current from the outside to the twenty anode power supply pads 102, sequential driving in which each column emits light at different timings can be performed.

Here, the VCSEL array 100H according to the ninth embodiment includes VCSELs 5A and 5B as the plurality of VCSELs 5. In the following description, the VCSEL 5A and the VCSEL 5B may be simply referred to as “VCSEL 5” when it is not necessary to distinguish them from each other.

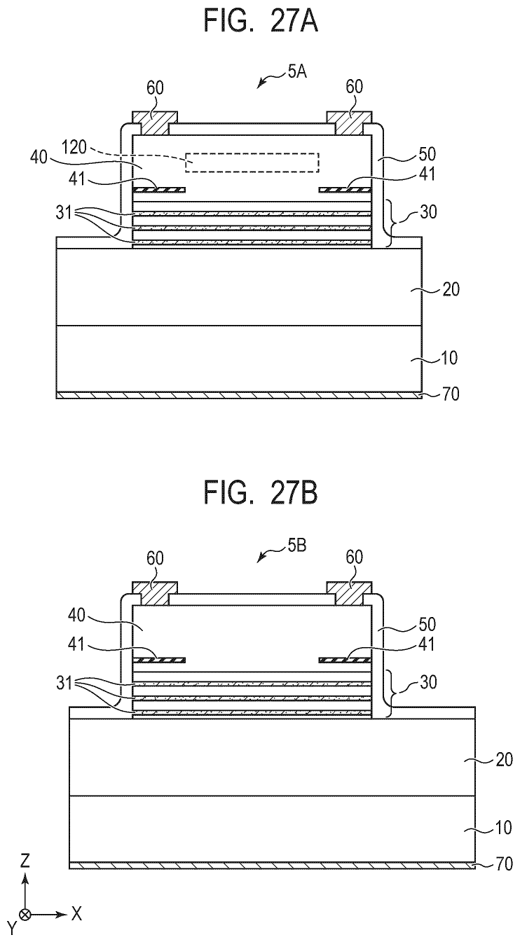

As illustrated in FIG. 27B, the VCSEL 5B includes an n-type GaAs substrate 10, a first DBR 20, a semiconductor resonator 30, a second DBR 40, an insulating film 50, an upper electrode 60, and a back electrode 70. The first DBR 20, the semiconductor resonator 30, the second DBR 40, and the upper electrode 60 are stacked in this order on the first surface of the n-type GaAs substrate 10. The back electrode 70 is provided on a second surface opposite to the first surface of the n-type GaAs substrate 10. Although these members are in direct contact with each other in FIG. 27B, other members may be provided therebetween in the VCSEL 5B. In addition, the above description is a description representing a structure, and does not limit the order of manufacturing each member. FIG. 27B is a cross-sectional view along line V2-V2 of FIG. 26.

Next, the VCSEL 5A will be described. The VCSEL 5A is different from the VCSEL 5B in that it has a proton implantation region 120, and otherwise has the same configuration as the VCSEL 5B. That is, as illustrated in FIG. 27A, the VCSEL 5A includes an n-type GaAs substrate 10, a first DBR 20, a semiconductor resonator 30, a second DBR 40, an insulating film 50, an upper electrode 60, and a back electrode 70. The first DBR 20, the semiconductor resonator 30, the second DBR 40, and the upper electrode 60 are stacked in this order on the first surface of the n-type GaAs substrate 10. The back electrode 70 is provided on a second surface opposite to the first surface of the n-type GaAs substrate 10. FIG. 27A is a cross-sectional view along line V1-V1 of FIG. 26.

In the ninth embodiment, the proton implantation region 120 is provided as means for changing the resistance value. The proton implantation region 120 is provided in a part of the second DBR 40 of the VCSEL 5A. As a result, the VCSEL 5A can lower the carrier density in the second DBR 40 in the current path flowing from the upper electrode 60 to the current confinement layer 41, and thus can increase the resistance value as compared with the VCSEL 5B.

The proton implantation region 120 can be formed by conventional methods Here, as described in the third embodiment, in the VCSEL 2 including the ITO layer 90 in the upper portion, since the current path is close to the center of the mesa, when the proton implantation region 120 is provided in such a configuration, the resistance value can be efficiently increased. In the ninth embodiment, since the light absorption rate of the second DBR 40 is also changed by injecting protons into the proton implantation region 120, the extraction efficiency is changed. Therefore, when it is desired to smooth the light quantity distribution in the array, it is desirable to design the arrangement of the VCSELs in the array in consideration of not only the current distribution but also the light quantity distribution.

Thus, VCSEL 5A has the proton implantation region 120 in second DBR 40, while VCSEL 5B does not have the proton implantation region 120 in second DBR 40. With this configuration, the VCSEL 5A and the VCSEL 5B have different resistance values between the upper electrode 60 and the back electrode 70. When a resistance value between the upper electrode 60 and the back electrode 70 of the VCSEL 5A is R1 and a resistance value between the upper electrode 60 and the back electrode 70 of the VCSEL 5B is R2, R1>R2. That is, since the VCSEL 5A has the proton implantation region 120, the resistance value is larger than that of the VCSEL 5B.

The plurality of VCSELs 5 is divided into two groups (first and second groups) according to the distance from the anode power supply pad 102. The VCSEL array 100H is configured such that the VCSELs in a group closer to the anode power supply pad 102 have a higher resistance. Specifically, the VCSEL 5A configures the VCSEL of the first group having a short distance from the anode power supply pad 102, and the VCSEL 5B configures the VCSEL of the second group having a long distance from the anode power supply pad 102. More specifically, as illustrated in FIG. 26, the 1st to 5th VCSELs of the first groups closer to the anode power supply pad 102 are configured by the VCSEL 5A having a large resistance value. The remaining 6th to 20th VCSELs of the second group are configured by VCSELs 5B having small resistance values. The VCSEL array 100H can make the currents injected into the VCSELs 5A and 5B more uniform by devising the arrangement of the two types of VCSELs 5A and 5B having different resistance values.

### Tenth Embodiment

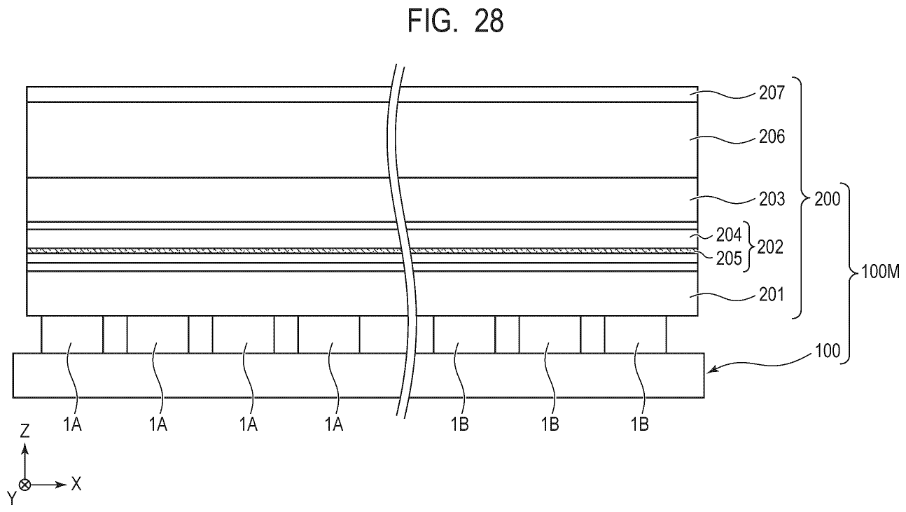

Next, an example in which the VCSEL array 100 is applied to a SWIR (Short Wavelength Infrared Region) band will be described. FIG. 28 is a cross-sectional view illustrating a configuration example of a VCSEL array 100M according to the tenth embodiment.

The VCSEL array 100M includes the VCSEL array 100 of the first embodiment and a VCSEL chip 200 and has a configuration in which the VCSEL chip 200 is bonded onto the VCSEL array 100.

The VCSEL chip 200 oscillates by optical excitation and includes a lower reflector 201 as a third reflector and a semiconductor resonator 202 as a second semiconductor resonator including a second active layer, as illustrated in FIG. 28. Further, the VCSEL chip 200 includes an upper reflector 203 as a fourth reflector, an InP substrate 206, and an AR (Anti Reflection) coating 207. In the VCSEL chip 200, the lower reflector 201, the semiconductor resonator 202, the upper reflector 203, the InP substrate 206, and the AR coat 207 are stacked in this order on the VCSEL array 100. The lower reflector 201 is configured by seven pairs of alternating laminations of SiO₂ and TiO₂ layers having an optical film thickness of ¼ λc. The semiconductor resonator 202 includes an InGaAsP light absorption layer 204 and five quantum well layers 205 configured by 8 nm-thick InGaAs (only one layer is illustrated). The quantum well layer 205 is excited by the light of the first wavelength emitted from the VCSEL array 100. The upper reflector 203 is configured by an alternating lamination of InP/InGaAsP having an optical film thickness of ¼ λc. The upper reflector 203 is configured to have a lower reflectance than the lower reflector 201. Therefore, the light of the second wavelength oscillated by the VCSEL chip 200 is extracted through the InP substrate 206. The AR coat 207 prevents reflection. Note that the light of the second wavelength is light of a wavelength different from that of the light of the first wavelength.

The VCSEL array 100 emits light having a wavelength of, for example, 940 nm to the VCSEL chip 200, and the light emitted to the VCSEL chip 200 passes through the lower reflector 201 and is absorbed by the InGaAsP light absorption layer 204 in the semiconductor resonator 202. The absorbed light generates electrons and holes, which enter the quantum well layer 205 and reach a density exceeding the transparent carrier density, resulting in gain. In this way, the VCSEL array 100M generates laser oscillation in the VCSEL chip 200 and emits laser light having a wavelength band of 1550 nm.

In the VCSEL array 100M, a portion that emits light at a wavelength of 1550 nm can be selected by selecting the anode wire 101 to be energized from among the plurality of anode wires 101 forming the VCSEL array 100. In addition, by the configuration in which the current distribution of the VCSEL array 100 is smoothed, this enables minimizing the space for wire between the VCSELs 1A and 1B while smoothing the light emission intensity distribution of the VCSELs 1A and 1B forming the VCSEL array 100. Thus, the VCSEL array 100M can reduce the chip size. Reduction in chip size leads not only to lower chip costs, but also to the miniaturization of optical systems, including lenses, and their cost reduction.

The VCSEL chip 200 on the side excited by light having a wavelength of 940 nm is a VCSEL having a wavelength of 1550 nm, but it is not limited to this. For example, an LED or a VCSEL array that is excited by light having a wavelength of 940 nm and emits light in a wavelength band of 1900 nm may be used.

Although the VCSEL array 100 according to the first embodiment is used as the VCSEL array to be excited, the configurations according to the second to tenth embodiments have the same effects. In either case, this enables minimizing the wire space and reducing the size of the VCSEL chip.

### Eleventh Embodiment

Next, a ranging device 300 according to an eleventh embodiment will be described. The ranging device 300 is, for example, a LiDAR in which the VCSEL array 100 or the like according to the first embodiment is used as a light source unit.

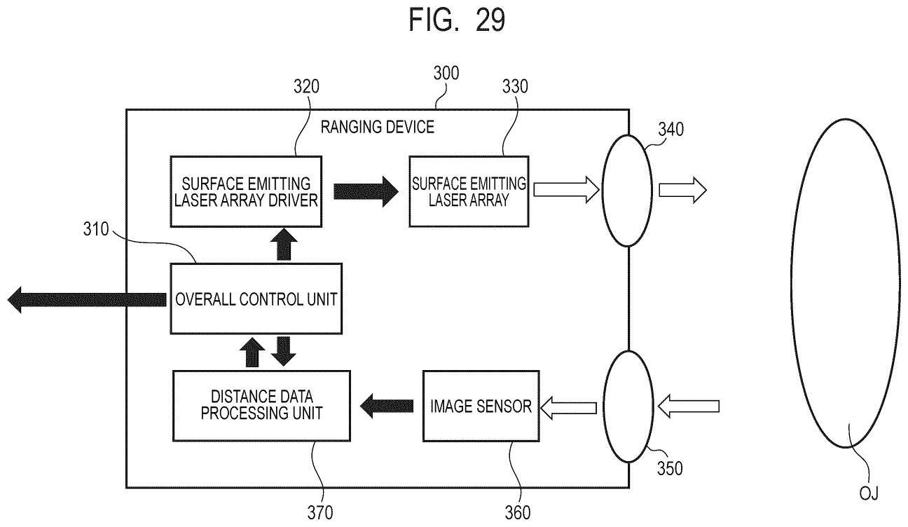

As illustrated in FIG. 29, the ranging device 300 includes an overall control unit 310, a surface emitting laser array driver 320, a surface emitting laser array 330, an optical system 340, an optical system 350, an image sensor 360, and a distance data processing unit 370.

The overall control unit 310 is configured by an information processing device or the like including a microcomputer and a logic circuit, and has a function as a central processing device that governs operations in the ranging device 300 such as operation control of each unit and various arithmetic processing.

The surface emitting laser array driver 320 is a driving unit that receives a driving signal from the overall control unit 310, generates a driving current for oscillating the surface emitting laser array 330, and outputs the driving current to the surface emitting laser array 330.

The surface emitting laser array 330 is configured by mounting the VCSEL array described in the first to tenth embodiments in a package.

The optical system 340 is an optical system that emits laser light generated by the surface emitting laser array 330 toward a range to be measured.

The optical system 350 is an optical system that guides the laser light reflected by the measurement object OJ included in the distance measurement object range to the image sensor 360. Although the optical system 340 and the optical system 350 are represented by one convex lens-shaped member in FIG. 29, they are not configured by only one convex lens system but are configured by a lens group in which a plurality of lenses are combined.

The image sensor 360 is, for example, a light receiving device in which CMOS (Complementary Metal-Oxide Semiconductor) optical sensors are arranged in an array. The image sensor 360 may be a light receiving device in which SPAD (Single Photon Avalanche Diode) optical sensors are arranged in an array.

The distance data processing unit 370 has a function as a distance information acquisition unit that generates information on the distance to the measurement object OJ present in the distance measurement object range based on the signal from the image sensor 360 and outputs the generated information. The distance data processing unit 370 acquires information on the distance to the measurement object OJ based on, for example, a time difference between a timing at which light is emitted from the surface emitting laser array 330 and a timing at which the image sensor 360 receives light. The distance data processing unit 370 may be electrically connected to the image sensor 360 and may be disposed in the same package as the image sensor 360 or may be disposed in a package different from the image sensor 360.

Next, the operation of the ranging device 300 will be described. First, a drive signal is output from the overall control unit 310 to the surface emitting laser array driver 320. Upon receiving the drive signal, the surface emitting laser array driver 320 outputs a drive current of a predetermined current value to the surface emitting laser array 330 to oscillate the surface emitting laser array 330. The laser light generated by the surface emitting laser array 330 is emitted toward the measurement object OJ through the optical system 340, and the light reflected by the measurement object OJ is incident on the image sensor 360 through the optical system 350. The image sensor 360 converts the optical signal of the incident light into an electrical signal, and outputs the converted electrical signal to the distance data processing unit 370. The distance data processing unit 370 calculates distance information based on a time difference between a timing at which light is emitted from the surface emitting laser array 330 and a timing at which the image sensor 360 receives light, and generates three-dimensional information based on the distance information.

The distance data processing unit 370 outputs the generated three-dimensional information to the overall control unit 310.

In the field of automobiles, the ranging device 300 is applicable to control that does not collide with another vehicle, control that performs automatic driving following another vehicle, and the like. Further, the ranging device 300 can be used for mobile object (mobile device) and mobile object detection systems of ships, aircrafts, industrial robots, or the like. Further, the ranging device 300 can be widely applied to a device that uses recognition of an object in a three-dimensional manner having distance information.

In addition, by using three-dimensional information having depth, the ranging device 300 can display a virtual object on the real world without a sense of discomfort in the image capturing device, the image processing device, and the display device. In addition, the ranging device 300 can also be applied to an apparatus that stores three-dimensional information together with image information and adds a function of correcting a blur or the like in a photographed image after photographing.

### Modified Embodiments

The present invention is not limited to the above-described embodiment, and various modifications are possible. For example, an example in which a part of the configuration of any of the embodiments is added to another embodiment or an example in which a part of the configuration of another embodiment is replaced with another embodiment is also an embodiment of the present invention.

For example, the semiconductor layer 80 and the proton implantation region 120 may be further provided for the VCSEL 2A including the ITO layer 90, or the semiconductor layer 80 and the proton implantation region 120 may be provided for the high peak value VCSEL 3A. In addition, the semiconductor layer 80 and the proton implantation region 120 may be provided for the VCSEL 4A in which the width of the non-oxidized region of the current confinement layer 41 is different, or the semiconductor layer 80 may be further provided for the VCSEL 5A including the proton implantation region 120.

In this way, means for changing the resistance value may be appropriately combined. Thus, the number of types of resistances of the VCSELs in the VCSEL array can be increased, and the current distribution can be further smoothed.

Further, the semiconductor layer 80 may be further provided for the VCSELs 3A and 3B having different widths of the non-oxidized region of the current confinement layer 41, or the semiconductor layer 80 may be further provided for the high peak value VCSEL 3A. Thus, the number of types of resistances of the VCSELs in the VCSEL array can be increased, and the current distribution can be further smoothed.

The plurality of VCSELs may include at least two types of VCSELs of VCSEL 1A, VCSEL 2A, VCSEL 3A, VCSEL 4A and VCSEL 5A.

The VCSEL 1A includes the semiconductor layer 80 between the upper electrode 60 and the second DBR 40, and the VCSEL 1B does not include the semiconductor layer 80 between the upper electrode 60 and the second DBR 40, but the configuration is not limited to these examples. For example, each of the VCSEL 1A and the VCSEL 1B may have the semiconductor layer 80 between the upper electrode 60 and the second DBR 40, and the film thickness of the semiconductor layer 80 of the VCSEL 1A may be thicker than the film thickness of the semiconductor layer 80 of the VCSEL 1B.

Although an example in which the VCSEL array includes four hundred VCSELs has been described, the number of VCSELs is not limited thereto and may be other numbers.

In addition, in each of the embodiments, the sequential anode wire configuration in which the arrays that simultaneously emit light are arranged in every one column has been described, but the present invention is not limited thereto, and for example, the present invention can be similarly applied to a case in which the arrays that simultaneously emit light are arranged in every two columns, every three columns, or every four or more columns. Further, the present invention can be similarly applied to, for example, a flash-type anode wire configuration in which the entire surface emits light at the same time. Specifically, for example, in the case where twenty arrays are arranged in the Y direction and twenty arrays are arranged in the X direction, and the anode wires are uniformly connected to all the arrays, the current injection amount in the center of the VCSEL array tends to be smaller than that in the outside. Even in such a configuration, when the resistance value of the VCSEL on the side closer to the anode power supply pad 102 in the current path is R1 and the resistance value of the VCSEL on the side farther from the anode power supply pad is R2, the first to tenth embodiments are appropriately applied alone or in combination so that R1>R2. Accordingly, this enables the current distribution to be smoothed across the entire array. Further, the current distribution can be further smoothed by increasing the kinds of resistors and appropriately arranging the VCSELs.

In addition, although the current confinement structure has been described by taking as an example an oxidation confinement layer formed by selectively oxidizing a part of the semiconductor layer, the current confinement structure is not limited thereto. The current confinement structure may be formed by other methods such as ion implantation.

Although an example in which the proton implantation region 120 is provided in the second DBR 40 which is a P-type semiconductor has been described, the present invention is not limited thereto. For example, instead of protons, donor impurities having a hole compensation effect may be ion-implanted. When the second DBR 40 is an N-type semiconductor, an acceptor impurity having an electron compensation effect may be ion-implanted instead of protons.

In addition, in the VCSELs 4A and 4B, an example in which both the semiconductor resonator 30 and the second DBR 40 are processed into the mesa shape has been described, but the present invention is not limited thereto, and at least the second DBR 40 may be processed into the mesa shape.

The disclosure of the above-mentioned embodiments includes the following configuration.

### Configuration 1

Alight source device comprising:
a plurality of semiconductor light emitting elements configured to stack, on a first surface side of a semiconductor substrate, a first reflector, a first semiconductor resonator including a first active layer, a second reflector, and a first electrode in order, and to stack a second electrode on a second surface of the semiconductor substrate opposite to the first surface;
a power supply pad configured to supply power to the plurality of semiconductor light emitting elements; and
a wire configured to connect each of the plurality of semiconductor light emitting elements to the power supply pad,
wherein the plurality of semiconductor light emitting elements are divided into a plurality of groups according to a distance from the power supply pad, and each of the plurality of groups includes at least one semiconductor light emitting element, and
wherein the semiconductor light emitting element in the group with a shorter distance to the power supply pad is configured to have a larger resistance value between the first electrode and the second electrode.

### Configuration 2

Alight source device comprising:
a plurality of semiconductor light emitting elements configured to stack, on a first surface side of a semiconductor substrate, a first reflector, a first semiconductor resonator including a first active layer, a second reflector, and a first electrode in order, and to stack a second electrode on a second surface of the semiconductor substrate opposite to the first surface;
a power supply pad configured to supply power to the plurality of semiconductor light emitting elements; and
a wire configured to connect each of the plurality of semiconductor light emitting elements to the power supply pad,
wherein the plurality of semiconductor light emitting elements are divided into a plurality of groups according to a length of a current path of the wire from the power supply pad, and each of the plurality of groups includes at least one semiconductor light emitting element, and
wherein the semiconductor light emitting element in the group with a shorter length of the current path of the wire to the power supply pad is configured to have a larger resistance value between the first electrode and the second electrode.

### Configuration 3

The light source device according to Configuration 1 or 2, wherein the plurality of groups include a first group and a second group including the semiconductor light emitting element whose resistance value is smaller than that of the semiconductor light emitting element of the first group.

### Configuration 4

The light source device according to Configuration 3,
wherein the plurality of groups include the first group, the second group, and a third group including the semiconductor light emitting element whose resistance value is smaller than that of the semiconductor light emitting element of the first group and larger than that of the semiconductor light emitting element of the second group, and
wherein the third group is disposed between the first group and the second group.

### Configuration 5

The light source device according to any one of Configurations 1 to 4, wherein the plurality of semiconductor light emitting elements include a transparent conductive film between the first electrode and the second reflector.

### Configuration 6

The light source device according to any one of Configurations 1 to 5, wherein the plurality of semiconductor light emitting elements include a saturable absorption layer in the first reflector.

### Configuration 7

The light source device according to Configuration 3 or 4, wherein the semiconductor light emitting element of the first group is formed such that a distance between the first electrode and the second electrode is longer than a distance between the first electrode and the second electrode of the semiconductor light emitting element of the second group, and due to the distance being longer than that of the semiconductor light emitting element of the second group, the resistance value between the first electrode and the second electrode is greater than that of the semiconductor light emitting element of the second group.

### Configuration 8

The light source device according to Configuration 5, wherein a contact area between the transparent conductive film and the second reflector in the semiconductor light emitting element of a first group among the plurality of groups is smaller than a contact area between the transparent conductive film and the second reflector in the semiconductor light emitting element of a second group among the plurality of groups.

### Configuration 9

The light source device according to Configuration 3, 4, 7 or 8, wherein at least the second reflector of the plurality of semiconductor light emitting elements is a mesa shape, and a width of the second reflector of the semiconductor light emitting element in the first group is narrower than a width of the second reflector of the semiconductor light emitting element in the second group.

### Configuration 10

The light source device according to Configuration 3, 4, 7, or 8, wherein the semiconductor light emitting element of the first group includes a proton implantation region within the second reflector, and by including the proton implantation region, the resistance value between the first electrode and the second electrode is larger than that of the semiconductor light emitting element of the second group.

### Configuration 11

The light source device according to any one of Configurations 1 to 10,
wherein the plurality of semiconductor light emitting elements stack, on a side of the second reflector opposite to the first semiconductor resonator, a third reflector, a second semiconductor resonator including a second active layer, and a fourth reflector in order,
wherein the second active layer is excited by light of a first wavelength emitted from the plurality of semiconductor light emitting elements and emits light of a second wavelength different from the first wavelength.

### Configuration 12

Alight source device comprising:
a plurality of semiconductor light emitting elements configured to stack, on a first surface side of a semiconductor substrate, a first reflector, a first semiconductor resonator including a first active layer, a second reflector, and a first electrode in order, and to stack a second electrode on a second surface of the semiconductor substrate opposite to the first surface;
a power supply pad configured to supply power to the plurality of semiconductor light emitting elements; and
a wire configured to connect each of the plurality of semiconductor light emitting elements to the power supply pad,
wherein the plurality of semiconductor light emitting elements are divided into a plurality of groups according to resistance of the wire from the power supply pad, and each of the plurality of groups includes at least one semiconductor light emitting element, and
wherein the semiconductor light emitting element in the group with a smaller resistance of the wire to the power supply pad is configured to have a larger resistance value between the first electrode and the second electrode.

### Configuration 13

The light source device according to Configuration 5, wherein the plurality of semiconductor light emitting elements include a saturable absorption layer in the first reflector.

### Configuration 14

The light source device according to Configuration 13,
wherein the plurality of groups include a first group and a second group including the semiconductor light emitting element whose resistance value is smaller than that of the semiconductor light emitting element of the first group, and
wherein the semiconductor light emitting element of the first group is formed such that a distance between the first electrode and the second electrode is longer than a distance between the first electrode and the second electrode of the semiconductor light emitting element of the second group, and due to the distance being longer than that of the semiconductor light emitting element of the second group, the resistance value between the first electrode and the second electrode is greater than that of the semiconductor light emitting element of the second group.

### Configuration 15

The light source device according to Configuration 14, wherein a contact area between the transparent conductive film and the second reflector in the semiconductor light emitting element of the first group is smaller than a contact area between the transparent conductive film and the second reflector in the semiconductor light emitting element of the second group.

### Configuration 16

The light source device according to Configuration 15, wherein at least the second reflector of the plurality of semiconductor light emitting elements is a mesa shape, and a width of the second reflector of the semiconductor light emitting element in the first group is narrower than a width of the second reflector of the semiconductor light emitting element in the second group.

### Configuration 17

The light source device according to Configuration 16, wherein the semiconductor light emitting element of the first group includes a proton implantation region within the second reflector, and by including the proton implantation region, the resistance value between the first electrode and the second electrode is larger than that of the semiconductor light emitting element of the second group.

### Configuration 18

A ranging device comprising:
the light source device according to any one of Configurations 1 to 17;
a light receiving device configured to receive light emitted from the light source device and reflected by an object to be measured; and
a distance information acquisition unit configured to acquire information on a distance to the object to be measured based on a time difference between a timing at which light is emitted from the light source device and a timing at which the light receiving device receives light.

The present invention enables the realization of a light source device capable of improving light emission uniformity across the plurality of semiconductor light emitting elements.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-200586, filed Nov. 28, 2023, which is hereby incorporated by reference herein in its entirety.

What is claimed is:

1. Alight source device comprising:
a plurality of semiconductor light emitting elements configured to stack, on a first surface side of a semiconductor substrate, a first reflector, a first semiconductor resonator including a first active layer, a second reflector, and a first electrode in order, and to stack a second electrode on a second surface of the semiconductor substrate opposite to the first surface;
a power supply pad configured to supply power to the plurality of semiconductor light emitting elements; and
a wire configured to connect each of the plurality of semiconductor light emitting elements to the power supply pad,
wherein the plurality of semiconductor light emitting elements are divided into a plurality of groups according to a distance from the power supply pad, and each of the plurality of groups includes at least one semiconductor light emitting element, and
wherein the semiconductor light emitting element in the group with a shorter distance to the power supply pad is configured to have a larger resistance value between the first electrode and the second electrode.

2. Alight source device comprising:
a plurality of semiconductor light emitting elements configured to stack, on a first surface side of a semiconductor substrate, a first reflector, a first semiconductor resonator including a first active layer, a second reflector, and a first electrode in order, and to stack a second electrode on a second surface of the semiconductor substrate opposite to the first surface;
a power supply pad configured to supply power to the plurality of semiconductor light emitting elements; and
a wire configured to connect each of the plurality of semiconductor light emitting elements to the power supply pad,
wherein the plurality of semiconductor light emitting elements are divided into a plurality of groups according to a length of a current path of the wire from the power supply pad, and each of the plurality of groups includes at least one semiconductor light emitting element, and
wherein the semiconductor light emitting element in the group with a shorter length of the current path of the wire to the power supply pad is configured to have a larger resistance value between the first electrode and the second electrode.

3. The light source device according to claim 1, wherein the plurality of groups include a first group and a second group including the semiconductor light emitting element whose resistance value is smaller than that of the semiconductor light emitting element of the first group.

4. The light source device according to claim 3,
wherein the plurality of groups include the first group, the second group, and a third group including the semiconductor light emitting element whose resistance value is smaller than that of the semiconductor light emitting element of the first group and larger than that of the semiconductor light emitting element of the second group, and
wherein the third group is disposed between the first group and the second group.

5. The light source device according to claim 1, wherein the plurality of semiconductor light emitting elements include a transparent conductive film between the first electrode and the second reflector.

6. The light source device according to claim 1, wherein the plurality of semiconductor light emitting elements include a saturable absorption layer in the first reflector.

7. The light source device according to claim 3, wherein the semiconductor light emitting element of the first group is formed such that a distance between the first electrode and the second electrode is longer than a distance between the first electrode and the second electrode of the semiconductor light emitting element of the second group, and due to the distance being longer than that of the semiconductor light emitting element of the second group, the resistance value between the first electrode and the second electrode is greater than that of the semiconductor light emitting element of the second group.

8. The light source device according to claim 5, wherein a contact area between the transparent conductive film and the second reflector in the semiconductor light emitting element of a first group among the plurality of groups is smaller than a contact area between the transparent conductive film and the second reflector in the semiconductor light emitting element of a second group among the plurality of groups.

9. The light source device according to claim 3, wherein at least the second reflector of the plurality of semiconductor light emitting elements is a mesa shape, and a width of the second reflector of the semiconductor light emitting element in the first group is narrower than a width of the second reflector of the semiconductor light emitting element in the second group.

10. The light source device according to claim 3, wherein the semiconductor light emitting element of the first group includes a proton implantation region within the second reflector, and by including the proton implantation region, the resistance value between the first electrode and the second electrode is larger than that of the semiconductor light emitting element of the second group.

11. The light source device according to claim 1,
wherein the plurality of semiconductor light emitting elements stack, on a side of the second reflector opposite to the first semiconductor resonator, a third reflector, a second semiconductor resonator including a second active layer, and a fourth reflector in order,
wherein the second active layer is excited by light of a first wavelength emitted from the plurality of semiconductor light emitting elements and emits light of a second wavelength different from the first wavelength.

12. Alight source device comprising:
a plurality of semiconductor light emitting elements configured to stack, on a first surface side of a semiconductor substrate, a first reflector, a first semiconductor resonator including a first active layer, a second reflector, and a first electrode in order, and to stack a second electrode on a second surface of the semiconductor substrate opposite to the first surface;
a power supply pad configured to supply power to the plurality of semiconductor light emitting elements; and
a wire configured to connect each of the plurality of semiconductor light emitting elements to the power supply pad,
wherein the plurality of semiconductor light emitting elements are divided into a plurality of groups according to resistance of the wire from the power supply pad, and each of the plurality of groups includes at least one semiconductor light emitting element, and
wherein the semiconductor light emitting element in the group with a smaller resistance of the wire to the power supply pad is configured to have a larger resistance value between the first electrode and the second electrode.

13. The light source device according to claim 5, wherein the plurality of semiconductor light emitting elements include a saturable absorption layer in the first reflector.

14. The light source device according to claim 13,
wherein the plurality of groups include a first group and a second group including the semiconductor light emitting element whose resistance value is smaller than that of the semiconductor light emitting element of the first group, and
wherein the semiconductor light emitting element of the first group is formed such that a distance between the first electrode and the second electrode is longer than a distance between the first electrode and the second electrode of the semiconductor light emitting element of the second group, and due to the distance being longer than that of the semiconductor light emitting element of the second group, the resistance value between the first electrode and the second electrode is greater than that of the semiconductor light emitting element of the second group.

15. The light source device according to claim 14, wherein a contact area between the transparent conductive film and the second reflector in the semiconductor light emitting element of the first group is smaller than a contact area between the transparent conductive film and the second reflector in the semiconductor light emitting element of the second group.

16. The light source device according to claim 15, wherein at least the second reflector of the plurality of semiconductor light emitting elements is a mesa shape, and a width of the second reflector of the semiconductor light emitting element in the first group is narrower than a width of the second reflector of the semiconductor light emitting element in the second group.

17. The light source device according to claim 16, wherein the semiconductor light emitting element of the first group includes a proton implantation region within the second reflector, and by including the proton implantation region, the resistance value between the first electrode and the second electrode is larger than that of the semiconductor light emitting element of the second group.

18. A ranging device comprising:
the light source device according to claim 1;
a light receiving device configured to receive light emitted from the light source device and reflected by an object to be measured; and
a distance information acquisition unit configured to acquire information on a distance to the object to be measured based on a time difference between a timing at which light is emitted from the light source device and a timing at which the light receiving device receives light.
